(19) United States
(12) Patent Application Publication
(10) Pub. No.: US 2024/0030264 A1
(43) Pub. Date: Jan. 25, 2024

(54) IMAGING ELEMENT AND IMAGING DEVICE

(71) Applicant: SONY SEMICONDUCTOR SOLUTIONS CORPORATION, KANAGAWA (JP)

(72) Inventors: AKIKO HONJO, KANAGAWA (JP); SHINICHI MIYAKE, KANAGAWA (JP)

(21) Appl. No.: 18/255,833

(22) PCT Filed: Dec. 2, 2021
(86) PCT No.: PCT/JP2021/044232

§ 371 Date: Jun. 2, 2023

(30) Foreign Application Priority Data
Dec. 10, 2020 (JP) 2020-205401

(51) Int. Cl. H01L 27/146

(52) U.S. Cl. CPC H01L 27/1463; H01L 27/14645

(57) ABSTRACT

To downsize an imaging element formed by stacking a plurality of semiconductor substrates. The imaging element includes a first semiconductor substrate and a second semiconductor substrate. The first semiconductor substrate includes a photoelectric conversion section that performs photoelectric conversion of incident light. The second semiconductor substrate includes a pixel circuit that generates an image signal according to a charge generated by the photoelectric conversion, an element isolating region that isolates elements of the pixel circuit, and a high impurity concentration region which is disposed below the element isolating region and having a high impurity concentration and is connected to the first semiconductor substrate in order to use a reference potential in common, with the first semiconductor substrate being stacked on a back surface side of the second semiconductor substrate.

### FIELD

The present disclosure relates to an imaging element and an imaging device.

### BACKGROUND

An imaging element that images a subject is implemented by using an imaging element having a configuration in which a plurality of substrates is stacked. The plurality of substrates corresponds to, for example, a substrate on which a pixel that converts incident light from the subject into an image signal using photoelectric conversion is formed and a substrate on which a circuit that generates a control signal of the pixel or a circuit that processes image signals is formed. A circuit that handles an analog image signal is disposed on the pixel. On the other hand, the circuit that processes image signals mainly uses a digital circuit that operates at a high speed. In this manner, with a configuration in which circuits having different characteristics are disposed on different substrates, it is possible to manufacture a substrate by applying an optimum process to these circuits. Further, the configuration of stacking these substrates making it also possible to reduce the area of the imaging element.

For example, there is proposed an imaging element in which a first substrate on which a photoelectric conversion element that performs photoelectric conversion of incident light is mainly disposed and a second substrate on which an amplification transistor that amplifies a signal generated by the photoelectric conversion element to generate an image signal is disposed are stacked to form a pixel (refer to Patent Literature 1, for example).

In this imaging element, a third substrate on which a circuit that generates a control signal of a pixel and a circuit that processes an image signal are formed is further stacked to form the imaging element. In addition, since the circuit constituting the pixel is divided into two substrates and stacked, a connecting location (contact) for using the reference potential of these substrates in common is disposed between the substrates. Here, the reference potential is a potential serving as a reference of a signal of a circuit of a pixel or a power supply voltage, and corresponds to a ground potential, for example.

### CITATION LIST

### Patent Literature

Patent Literature 1: WO 2020/105713 A

### SUMMARY

### Technical Problem

The above-described conventional technique has a problem of difficulty in downsizing the substrate. This is because there is a need to have a region where a contact is disposed on the first substrate, the second substrate, and the third substrate. In particular, in the second substrate stacked in the middle, a contact with the first substrate and a contact with the third substrate are disposed. There is a need to a region where these contacts are to be disposed, increasing the area of the substrate.

In view of this, regarding an imaging element and an imaging device having a configuration in which a plurality of semiconductor substrates is stacked, the present disclosure proposes an imaging element and an imaging device that can be downsized.

### Solution to Problem

An imaging element according to the present disclosure includes: a first semiconductor substrate including a photoelectric conversion section that performs photoelectric conversion of incident light; and a second semiconductor substrate that includes a pixel circuit that generates an image signal according to a charge generated by the photoelectric conversion, an element isolating region that isolates elements of the pixel circuit, and a high impurity concentration region which is disposed below the element isolating region and having a high impurity concentration and is connected to the first semiconductor substrate in order to use a reference potential in common, with the first semiconductor substrate being stacked on a back surface side of the second semiconductor substrate.

### BRIEF DESCRIPTION OF DRAWINGS

FIG. 1 is a block diagram depicting an example of a functional configuration of an imaging device according to an embodiment of the present disclosure.

FIG. 2 is a schematic plan view depicting a schematic configuration of the imaging device depicted in FIG. 1.

FIG. 3 is a schematic view depicting a cross-sectional configuration taken along line III-III′ depicted in FIG. 2.

FIG. 4 is an equivalent circuit diagram depicting an example of a configuration of a pixel sharing unit according to an embodiment of the present disclosure.

FIG. 5 is a diagram depicting a configuration example of the pixel sharing unit according to the embodiment of the present disclosure.

FIG. 6 is a cross-sectional view depicting a configuration example of the imaging device according to the embodiment of the present disclosure.

FIG. 7 is a diagram depicting a configuration example of a pixel sharing unit according to a first embodiment of the present disclosure.

FIG. 8A is a diagram depicting an example of a method of manufacturing the pixel array section according to the first embodiment of the present disclosure.

FIG. 8B is a diagram depicting an example of the method of manufacturing the pixel array section according to the first embodiment of the present disclosure.

FIG. 8C is a diagram depicting an example of the method of manufacturing the pixel array section according to the first embodiment of the present disclosure.

FIG. 8D is a diagram depicting an example of the method of manufacturing the pixel array section according to the first embodiment of the present disclosure.

FIG. 8E is a diagram depicting an example of the method of manufacturing the pixel array section according to the first embodiment of the present disclosure.

FIG. 8F is a diagram depicting an example of the method of manufacturing the pixel array section according to the first embodiment of the present disclosure.

FIG. 8G is a diagram depicting an example of the method of manufacturing the pixel array section according to the first embodiment of the present disclosure.

FIG. 8H is a diagram depicting an example of the method of manufacturing the pixel array section according to the first embodiment of the present disclosure.

FIG. 8I is a diagram depicting an example of the method of manufacturing the pixel array section according to the first embodiment of the present disclosure.

FIG. 8J is a diagram depicting an example of the method of manufacturing the pixel array section according to the first embodiment of the present disclosure.

FIG. 8K is a diagram depicting an example of the method of manufacturing the pixel array section according to the first embodiment of the present disclosure.

FIG. 8L is a diagram depicting an example of the method of manufacturing the pixel array section according to the first embodiment of the present disclosure.

FIG. 8M is a diagram depicting an example of the method of manufacturing the pixel array section according to the first embodiment of the present disclosure.

FIG. 8N is a diagram depicting an example of the method of manufacturing the pixel array section according to the first embodiment of the present disclosure.

FIG. 8O is a diagram depicting an example of the method of manufacturing the pixel array section according to the first embodiment of the present disclosure.

FIG. 9 is a diagram depicting a configuration example of a pixel sharing unit according to a second embodiment of the present disclosure.

FIG. 10A is a diagram depicting an example of a method of manufacturing a second connecting location according to the second embodiment of the present disclosure.

FIG. 10B is a diagram depicting an example of the method of manufacturing the second connecting location according to the second embodiment of the present disclosure.

FIG. 100 is a diagram depicting an example of the method of manufacturing the second connecting location according to the second embodiment of the present disclosure.

FIG. 11A is a diagram depicting another example of the method of manufacturing the second connecting location according to the second embodiment of the present disclosure.

FIG. 11B is a diagram depicting another example of the method of manufacturing the second connecting location according to the second embodiment of the present disclosure.

FIG. 11C is a diagram depicting another example of the method of manufacturing the second connecting location according to the second embodiment of the present disclosure.

FIG. 11D is a diagram depicting another example of the method of manufacturing the second connecting location according to the second embodiment of the present disclosure.

FIG. 12 is a diagram depicting a configuration example of a pixel sharing unit according to a third embodiment of the present disclosure.

FIG. 13A is a diagram depicting a configuration example of a pixel sharing unit according to a fourth embodiment of the present disclosure.

FIG. 13B is a diagram depicting another configuration example of the pixel sharing unit according to the fourth embodiment of the present disclosure.

FIG. 14 is a diagram depicting an example of a schematic configuration of an imaging system including the imaging device according to the embodiments and their modifications.

FIG. 15 is a diagram depicting an example of an imaging procedure of the imaging system depicted in FIG. 14.

FIG. 16 is a block diagram depicting an example of schematic configuration of a vehicle control system.

FIG. 17 is a diagram of assistance in explaining an example of installation positions of an outside-vehicle information detecting section and an imaging section.

FIG. 18 is a view depicting an example of a schematic configuration of an endoscopic surgery system.

FIG. 19 is a block diagram depicting an example of a functional configuration of a camera head and a camera control unit (CCU).

### DESCRIPTION OF EMBODIMENTS

Embodiments of the present disclosure will be described below in detail with reference to the drawings. The description will be given in the following order. Note that, in each of the following embodiments, the same parts are denoted by the same reference symbols, and a repetitive description thereof will be omitted.
1. First Embodiment
2. Second Embodiment
3. Third Embodiment
4. Fourth Embodiment
5. Application Example
6. Example of application to mobile body
7. Example of application to endoscopic surgery system

### 1. First Embodiment

[Functional Configuration of Imaging Device 1]

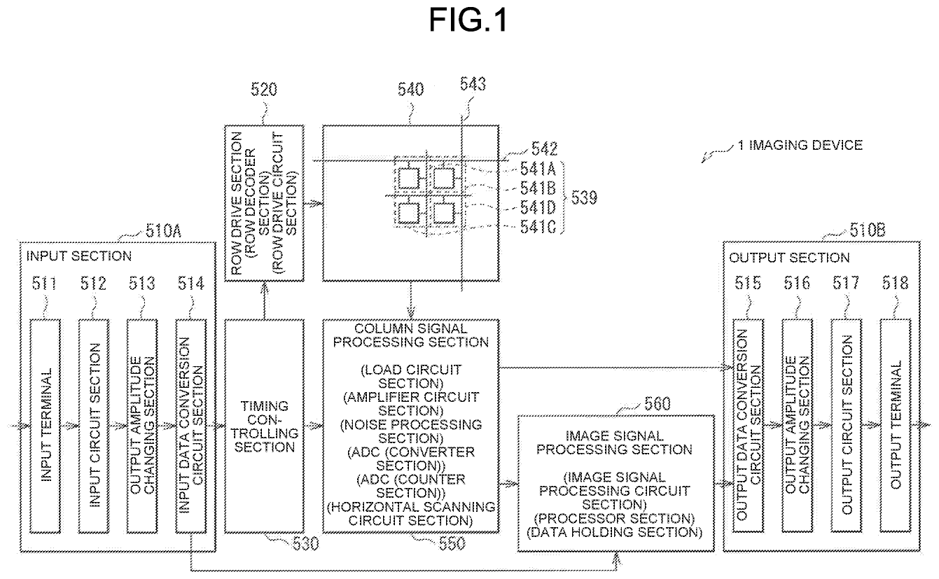

FIG. 1 is a block diagram depicting an example of a functional configuration of an imaging device (imaging device 1) according to an embodiment of the present disclosure.

The imaging device 1 of FIG. 1 includes, for example, an input section 510A, a row drive section 520, a timing controlling section 530, a pixel array section 540, a column signal processing section 550, an image signal processing section 560, and an output section 510B.

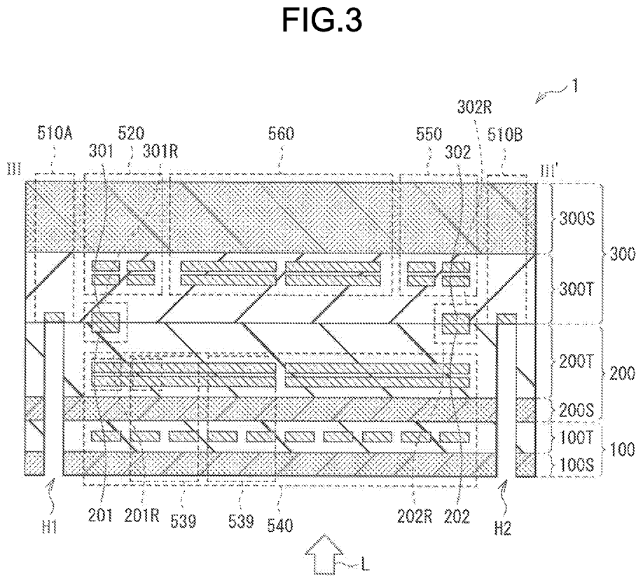

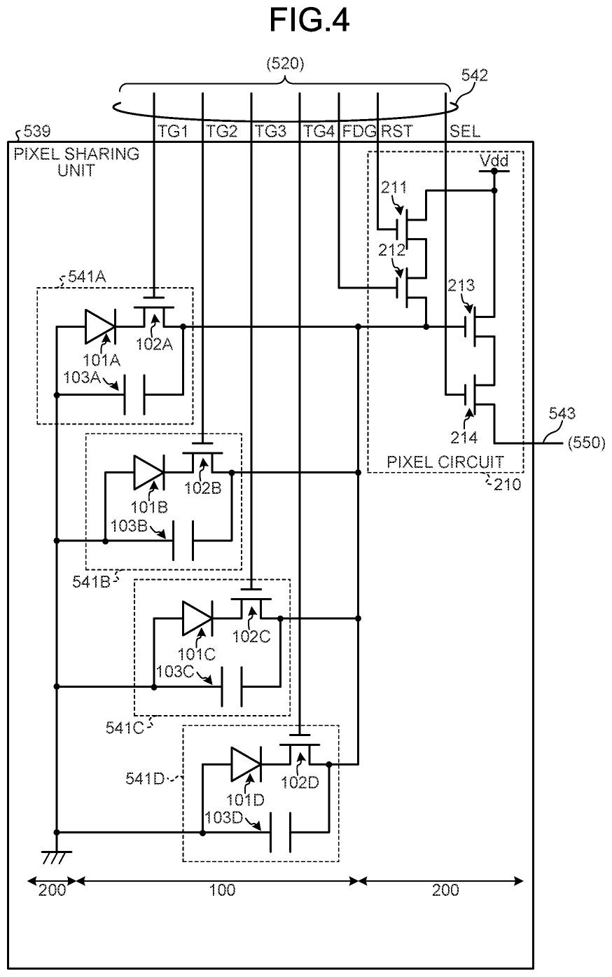

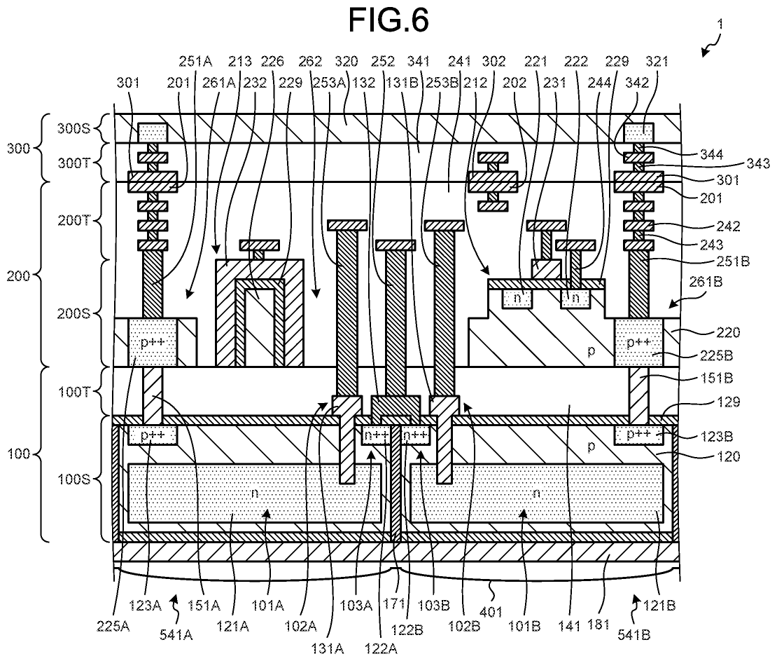

In the pixel array section 540, pixels 541 are repeatedly disposed in an array. More specifically, a pixel sharing unit 539 including a plurality of pixels is a repeating unit, and is repeatedly disposed in an array including a row direction and a column direction. In the present specification, for convenience, the row direction may be referred to as an H direction, and the column direction orthogonal to the row direction may be referred to as a V direction. In the example of FIG. 1, one pixel sharing unit 539 includes four pixels (pixels 541A, 541B, 541C, and 541D). Each of the pixels 541A, 541B, 541C, and 541D includes a photoelectric conversion section 101 (depicted in FIG. 6 and the like described below). The pixel sharing unit 539 is a unit of sharing one pixel circuit (a pixel circuit 210 in FIG. 3 described below). In other words, one pixel circuit (the pixel circuit 210 to be described below) is provided for every four pixels (pixels 541A, 541B, 541C, and 541D). By allowing the pixel circuit to operate in time division, a pixel signal of each of the pixels 541A, 541B, 541C, and 541D is sequentially read out. The pixels 541A, 541B, 541C, and 541D are each disposed in 2 rows×2 columns, for example. The pixel array section 540 includes a plurality of row drive signal lines 542 and a plurality of vertical signal lines (column readout lines) 543 together with the pixels 541A, 541B, 541C, and 541D. The row drive signal line 542 drives the pixels 541 included in each of the plurality of pixel sharing units 539 disposed side by side in the row direction in the pixel array section 540. In the pixel sharing unit 539, individual pixels disposed side by side in the row direction are driven. As will be described in detail below with reference to FIG. 4, the pixel sharing unit 539 is provided with a plurality of transistors. In order to drive each of the plurality of transistors, the plurality of row drive signal lines 542 is connected to one pixel sharing unit 539. The pixel sharing unit 539 is connected to the vertical signal line (column readout line) 543. A pixel signal is read out from each of the pixels 541A, 541B, 541C, and 541D included in the pixel sharing unit 539 via the vertical signal line (column readout line) 543.

The row drive section 520 includes, for example, a row address controlling section that determines a position of a row for pixel drive, in other words, a row decoder section, and a row drive circuit section that generates a signal for driving the pixels 541A, 541B, 541C, and 541D.

The column signal processing section 550 includes, for example, a load circuit section connected to the vertical signal line 543 and configured to form a source follower circuit with the pixels 541A, 541B, 541C, and 541D (pixel sharing unit 539). The column signal processing section 550 may include an amplifier circuit section that amplifies a signal read out from the pixel sharing unit 539 via the vertical signal line 543. The column signal processing section 550 may include a noise processing section. The noise processing section removes system noise levels from the signal read out from the pixel sharing unit 539 as a result of photoelectric conversion, for example.

The column signal processing section 550 includes an analog-to-digital converter (ADC), for example. The analog-to-digital converter converts the signal read out from the pixel sharing unit 539 or the noise-processed analog signal into a digital signal. The ADC includes, for example, a comparator section and a counter section. The comparator section compares an analog signal to be converted with a reference signal for comparison. The counter section is supposed to count the time until the comparison result in the comparator section is inverted. The column signal processing section 550 may include a horizontal scanning circuit section that performs control to scan the readout column.

The timing controlling section 530 supplies a signal controlling timing to the row drive section 520 and the column signal processing section 550 on the basis of the reference clock signal and the timing control signal input to the device.

The image signal processing section 560 is a circuit that applies various types of signal processing on data obtained as a result of photoelectric conversion, in other words, data obtained as a result of an imaging operation in the imaging device 1. The image signal processing section 560 includes, for example, an image signal processing circuit section and a data holding section. The image signal processing section 560 may include a processor section.

An example of signal processing executed in the image signal processing section 560 is a tone curve correction process of increasing levels of gradations in a case where the AD converted imaging data is data obtained by imaging a dark subject and reducing the levels of gradations in a case where the AD converted imaging data is data obtained by imaging a bright subject. In this case, it is desirable to preliminarily store, in the data holding section of the image signal processing section 560, the characteristic data of the tone curve, that is, which tone curve is to be used as a bases of the correction of gradation of the imaging data.

The input section 510A is, for example, a section provided for inputting the above-described reference clock signal, the timing control signal, the characteristic data, and the like from the outside of the device to the imaging device 1. The timing control signal is, for example, a vertical synchronization signal, a horizontal synchronization signal, or the like. The characteristic data is data to be stored in the data holding section of the image signal processing section 560, for example. The input section 510A includes an input terminal 511, an input circuit section 512, an input amplitude changing section 513, an input data conversion circuit section 514, and a power supply section (not depicted), for example.

The input terminal 511 is an external terminal for inputting data. The input circuit section 512 is a unit provided for capturing a signal input to the input terminal 511 into the imaging device 1. The input amplitude changing section 513 changes the amplitude of the signal captured by the input circuit section 512 to an amplitude highly usable inside the imaging device 1. The input data conversion circuit section 514 changes the arrangement of data strings of the input data. The input data conversion circuit section 514 is constituted with a serial-to-parallel conversion circuit, for example. The serial-to-parallel conversion circuit converts a serial signal received as input data into a parallel signal. The input section 510A can omit the input amplitude changing section 513 and the input data conversion circuit section 514. The power supply section supplies power set to various voltages required inside the imaging device 1 on the basis of power supplied from the outside to the imaging device 1.

When the imaging device 1 is connected to an external memory device, the input section 510A may be provided with a memory interface circuit that receives data from the external memory device. Examples of the external memory device include a flash drive, SRAM, and DRAM.

The output section 510B outputs image data to the outside of the device. Examples of the image data include image data captured by the imaging device 1, image data that has undergone signal processing performed by the image signal processing section 560, and the like. The output section 510B includes, for example, an output data conversion circuit section 515, an output amplitude changing section 516, an output circuit section 517, and an output terminal 518.

The output data conversion circuit section 515 is, for example, constituted with a parallel-to-serial conversion circuit, and thus, the output data conversion circuit section 515 converts a parallel signal used inside the imaging device 1 into a serial signal. The output amplitude changing section 516 changes the amplitude of a signal used inside the imaging device 1. The signal having amplitude changed will have high usability in an external device connected to the outside of the imaging device 1. The output circuit section 517 is a circuit that outputs data from the inside of the imaging device 1 to the outside of the device. The output circuit section 517 also drives wiring outside the imaging device 1 connected to the output terminal 518. Data is output from the imaging device 1 to the outside of the device via the output terminal 518. The output section 510B can omit the output data conversion circuit section 515 and the output amplitude changing section 516.

When the imaging device 1 is connected to an external memory device, the output section 510B may be provided with a memory interface circuit that outputs data to the external memory device. Examples of the external memory device include a flash drive, SRAM, and DRAM. [Schematic configuration of imaging device 1]

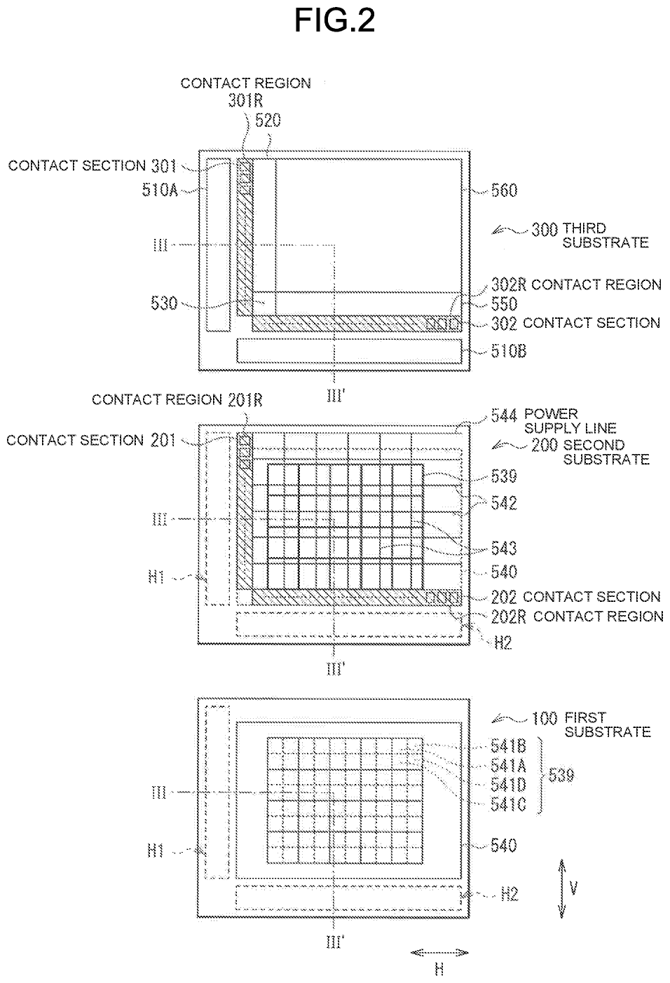

FIGS. 2 and 3 depict an example of a schematic configuration of the imaging device 1. The imaging device 1 includes three substrates (a first substrate 100, a second substrate 200, and a third substrate 300). FIG. 2 schematically depicts a planar configuration of each of the first substrate 100, the second substrate 200, and the third substrate 300. FIG. 3 schematically depicts a cross-sectional configuration of the first substrate 100, the second substrate 200, and the third substrate 300 stacked on each other. FIG. 3 corresponds to the cross-sectional configuration taken along line III-III′ depicted in FIG. 2. The imaging device 1 is an imaging device having a three-dimensional structure formed by bonding three substrates (the first substrate 100, the second substrate 200, and the third substrate 300). The first substrate 100 includes a semiconductor layer 100S and a wiring layer 100T. The second substrate 200 includes a semiconductor layer 200S and a wiring layer 200T. The third substrate 300 includes a semiconductor layer 300S and a wiring layer 300T. Here, a combination of the wiring included in each substrate of the first substrate 100, the second substrate 200, and the third substrate 300 together with an interlayer insulating film around the wiring is referred to as wiring layers (100T, 200T, and 300T) provided on each of the substrates (the first substrate 100, the second substrate 200, and the third substrate 300) for convenience. The first substrate 100, the second substrate 200, and the third substrate 300 are stacked in this order, and specifically, the layers are stacked in order of the semiconductor layer 100S, the wiring layer 100T, the semiconductor layer 200S, the wiring layer 200T, the wiring layer 300T, and the semiconductor layer 300S in a stacking direction. Specific configurations of the first substrate 100, the second substrate 200, and the third substrate 300 will be described below. The arrow depicted in FIG. 3 indicates the incident direction of light L on the imaging device 1. In the following cross-sectional views in the present specification, the light incident side in the imaging device 1 may be referred to as “lower”, “lower side”, or “below”, and the side opposite to the light incident side may be referred to as “upper”, “upper side”, or “above” for convenience. In addition, in the present specification, for convenience, in a substrate including a semiconductor layer and a wiring layer, a side of the wiring layer may be referred to as a front surface, and a side of the semiconductor layer may be referred to as a back surface. The description of the specification is not limited to the above terms. The imaging device 1 is, for example, a back-illuminated imaging device in which light enters from the back surface side of the first substrate 100 having a photodiode.

Both the pixel array section 540 and the pixel sharing unit 539 included in the pixel array section 540 are constituted by using both the first substrate 100 and the second substrate 200. The first substrate 100 is provided with the plurality of pixels 541A, 541B, 541C, and 541D included in the pixel sharing unit 539. Each of these pixels 541 includes a photodiode (photoelectric conversion section 101 described below) and a transfer transistor (charge transfer section 102 described below). The second substrate 200 is provided with a pixel circuit (the pixel circuit 210 to be described below) included in the pixel sharing unit 539. The pixel circuit reads out the pixel signal transferred from the photodiode of each of the pixels 541A, 541B, 541C, and 541D via the transfer transistor, or resets the photodiode. In addition to such a pixel circuit, the second substrate 200 includes a plurality of row drive signal lines 542 extending in the row direction and a plurality of vertical signal lines 543 extending in the column direction. The second substrate 200 further includes a power supply line 544 extending in the row direction. The third substrate 300 includes, for example, an input section 510A, a row drive section 520, a timing controlling section 530, a column signal processing section 550, an image signal processing section 560, and an output section 510B. The region in which the row drive section 520 is located partially overlaps the pixel array section 540 in the stacking direction of the first substrate 100, the second substrate 200, and the third substrate 300 (hereinafter, simply referred to as the stacking direction), for example. More specifically, the row drive section 520 is provided in a region overlapping the vicinity of an end of the pixel array section 540 in the H direction in the stacking direction (FIG. 2). The column signal processing section 550 is provided, for example, in a region partially overlapping the pixel array section 540 in the stacking direction. More specifically, the column signal processing section 550 is provided in a region overlapping the vicinity of the end of the pixel array section 540 in the V direction, in the stacking direction (FIG. 2). Although not depicted, the input section 510A and the output section 510B may be disposed in a portion other than the third substrate 300, and may be disposed on the second substrate 200, for example. Alternatively, the input section 510A and the output section 510B may be provided on the back surface (light incident surface) side of the first substrate 100. The pixel circuit provided on the second substrate 200 may also be referred to as a pixel transistor circuit, a pixel transistor group, a pixel transistor, a pixel readout circuit, or a readout circuit as an alternative term. In the present specification, the term “pixel circuit” is used.

The first substrate 100 and the second substrate 200 are electrically connected by a through-substrate electrode (through-substrate electrodes 252, 253A and 253B of FIG. 6 to be described below), for example. The second substrate 200 and the third substrate 300 are electrically connected via contact sections 201, 202, 301, and 302, for example. The contact sections 201 and 202 are provided on the second substrate 200, while the contact sections 301 and 302 are provided on the third substrate 300. The contact section 201 of the second substrate 200 is in contact with the contact section 301 of the third substrate 300, while the contact section 202 of the second substrate 200 is in contact with the contact section 302 of the third substrate 300. The second substrate 200 has a contact region 201R including a plurality of the contact sections 201 and a contact region 202R including a plurality of the contact sections 202. The third substrate 300 has a contact region 301R including a plurality of the contact sections 301 and a contact region 302R including a plurality of the contact sections 302. The contact regions 201R and 301R are provided between the pixel array section 540 and the row drive section 520 in the stacking direction (FIG. 3). In other words, the contact regions 201R and 301R are provided, for example, in a region where the row drive section 520 (on the third substrate 300) and the pixel array section 540 (on the second substrate 200) overlap each other in the stacking direction or in a region in their vicinity. The contact regions 201R and 301R are disposed at ends in the H direction in such regions, for example (FIG. 2). In the third substrate 300, for example, the contact region 301R is provided at a position overlapping a part of the row drive section 520, specifically the end of the row drive section 520 in the H direction (FIGS. 2 and 3). The contact sections 201 and 301 connect, for example, the row drive section 520 provided on the third substrate 300 and the row drive signal line 542 provided on the second substrate 200 to each other. For example, the contact sections 201 and 301 may connect the input section 510A provided on the third substrate 300, the power supply line 544, and a reference potential line (a ground line described below) to each other. The contact regions 202R and 302R are provided between the pixel array section 540 and the column signal processing section 550 in the stacking direction (FIG. 3). In other words, the contact regions 202R and 302R are provided, for example, in a region where the column signal processing section 550 (on the third substrate 300) and the pixel array section 540 (on the second substrate 200) overlap each other in the stacking direction or in a region in their vicinity. The contact regions 202R and 302R are disposed at ends in the V direction in such regions, for example (FIG. 2). In the third substrate 300, for example, the contact region 301R is provided at a position overlapping a part of the column signal processing section 550, specifically, the end of the column signal processing section 550 in the V direction (FIGS. 2 and 3). The contact sections 202 and 302 are provided for connecting a pixel signal (a signal corresponding to the amount of charge generated as a result of photoelectric conversion in a photodiode) output from each of the plurality of pixel sharing units 539 included in the pixel array section 540 to the column signal processing section 550 provided on the third substrate 300. The pixel signal is to be transmitted from the second substrate 200 to the third substrate 300.

FIG. 3 is an example of a cross-sectional view of the imaging device 1 as described above. The first substrate 100, the second substrate 200, and the third substrate 300 are electrically connected to each other via the wiring layers 100T, 200T, and 300T. For example, the imaging device 1 includes an electrical connecting location that electrically connects the second substrate 200 and the third substrate 300 to each other. Specifically, the contact sections 201, 202, 301, and 302 are formed with electrodes formed of a conductive material. The conductive material is formed of, for example, a metal material such as copper (Cu), aluminum (Al), or gold (Au). By directly bonding wiring lines formed as electrodes, for example, the contact regions 201R, 202R, 301R, and 302R electrically connect the second substrate and the third substrate to each other, enabling signal input and/or output between the second substrate 200 and the third substrate 300.

An electrical connecting location that electrically connects the second substrate 200 and the third substrate 300 can be provided at a desired location. For example, as described as the contact regions 201R, 202R, 301R, and 302R in FIG. 3, the contact regions may be provided in a region overlapping the pixel array section 540 in the stacking direction. The electrical connecting location may be provided in a region not overlapping the pixel array section 540 in the stacking direction. Specifically, it may be provided in a region overlapping a peripheral portion disposed outside the pixel array section 540 in the stacking direction.

The first substrate 100 and the second substrate 200 are provided with connection holes H1 and H2, for example. The connection holes H1 and H2 penetrate the first substrate 100 and the second substrate 200 (FIG. 3). The connection holes H1 and H2 are provided outside the pixel array section 540 (or a portion overlapping the pixel array section 540) (FIG. 2). For example, the connection hole H1 is disposed outside the pixel array section 540 in the H direction, while the connection hole H2 is disposed outside the pixel array section 540 in the V direction. For example, the connection hole H1 reaches the input section 510A provided in the third substrate 300, while the connection hole H2 reaches the output section 510B provided in the third substrate 300. The connection holes H1 and H2 may be hollow, and may at least a partially contain a conductive material. For example, there is a configuration in which a bonding wire is connected to an electrode formed as the input section 510A and/or the output section 510B. Alternatively, there is a configuration in which the electrode formed as the input section 510A and/or the output section 510B is connected to the conductive material provided in the connection holes H1 and H2. The conductive material provided in the connection holes H1 and H2 may be embedded in a part or all of the connection holes H1 and H2, and the conductive material may be formed on side walls of the connection holes H1 and H2.

FIG. 3 is a case of a structure in which the input section 510A and the output section 510B are provided on the third substrate 300, but the present disclosure is not limited thereto. For example, by sending a signal of the third substrate 300 to the second substrate 200 via the wiring layers 200T and 300T, the input section 510A and/or the output section 510B can be provided on the second substrate 200. Similarly, by sending a signal of the second substrate 200 to the first substrate 1000 via the wiring layers 100T and 200T, the input section 510A and/or the output section 510B can be provided on the first substrate 100.

Note that the imaging device 1 and the pixel array section 540 are examples of an imaging element described in the claims.

FIG. 4 is an equivalent circuit diagram depicting an example of a configuration of the pixel sharing unit. The pixel sharing unit 539 includes the plurality of pixels 541 (FIG. 4 depicts four pixels 541, namely, the pixels 541A, 541B, 541C, and 541D), one pixel circuit 210 connected to the plurality of pixels 541, and a vertical signal line 543 connected to the pixel circuit 210. The pixel circuit 210 includes, for example, four transistors, specifically, an amplification transistor 213, a selection transistor 214, a reset transistor 211, and a capacitance switching transistor 212. As described above, by operating one pixel circuit 210 in time division, the pixel sharing unit 539 is configured to sequentially output the pixel signals of the four pixels 541 (pixels 541A, 541B, 541C, and 541D) included in the pixel sharing unit 539 to the vertical signal line 543. The mode in which one pixel circuit 210 is connected to the plurality of pixels 541 and pixel signals of the plurality of pixels 541 are output by the one pixel circuit 210 in time division is referred to as a mode in which “the plurality of pixels 541 shares one pixel circuit 210”.

The pixels 541A, 541B, 541C, and 541D have components common to each other.

The pixels 541A, 541B, 541C, and 541D include, for example, a photoelectric conversion section 101, a charge transfer section 102 electrically connected to the photoelectric conversion section 101, and a charge holding section 103 electrically connected to the charge transfer section 102. The photoelectric conversion section 101 (photoelectric conversion sections 101A, 101B, 101C, and 101D) has a cathode electrically connected to a source of the charge transfer section 102 and has an anode electrically connected to a reference potential line (for example, a ground line). The photoelectric conversion section 101 performs photoelectric conversion of incident light and generates a charge corresponding to the amount of received light. The charge transfer section 102 (charge transfer sections 102A, 102B, 102C, and 102D) is an n-channel MOS transistor, for example. The charge transfer section 102 has a drain electrically connected to the charge holding section 103 and has a gate electrically connected to a drive signal line (signal lines TG1, TG2, TG3, and TG4). This drive signal line is a part of the plurality of row drive signal lines 542 (refer to FIG. 1) connected to one pixel sharing unit 539. The charge transfer section 102 transfers the charge generated in the photoelectric conversion section 101 to the charge holding section 103. The charge holding section 103 (charge holding sections 103A, 103B, 103C, and 103D) is an n-type diffusion layer region formed in the p-type semiconductor layer. Such charge holding section 103 is referred to as floating diffusion (FD). The charge holding section 103 is a charge holding means that temporarily holds the charge transferred from the photoelectric conversion section 101, and is a charge-voltage conversion means that generates a voltage corresponding to the charge amount.

The four charge holding sections 103 (charge holding sections 103A, 103B, 103C, and 103D) included in one pixel sharing unit 539 are electrically connected to each other and electrically connected to the gate of the amplification transistor 213 and the source of the capacitance switching transistor 212. The drain of the capacitance switching transistor 212 is connected to the source of the reset transistor 211, while the gate of the capacitance switching transistor 212 is connected to a drive signal line FDG. This drive signal line FDG is a part of the plurality of row drive signal lines 542 connected to one pixel sharing unit 539. The drain of the reset transistor 211 is connected to a power supply line Vdd, while the gate of the reset transistor 211 is connected to the drive signal line RST. This drive signal line RST is a part of the plurality of row drive signal lines 542 connected to one pixel sharing unit 539. The gate of the amplification transistor 213 is connected to the charge holding section 103, the drain of the amplification transistor 213 is connected to the power supply line Vdd, and the source of the amplification transistor 213 is connected to the drain of the selection transistor 214. The source of the selection transistor 214 is connected to the vertical signal line 543, while the gate of the selection transistor 214 is connected to the drive signal line SEL. This drive signal line SEL is a part of the plurality of row drive signal lines 542 connected to one pixel sharing unit 539.

When the charge transfer section 102 is turned on, the charge transfer section 102 transfers the charge of the photoelectric conversion section 101 to the charge holding section 103. A gate (transfer gate) of the charge transfer section 102 includes, for example, an electrode referred to as a vertical electrode, and is provided to extend from a front surface of a semiconductor layer (a semiconductor layer 100S in FIG. 6 to be described below) to a depth reaching the photoelectric conversion section 101 as depicted in FIG. 6 to be described below. The reset transistor 211 resets the potential of the charge holding section 103 to a predetermined potential. When the reset transistor 211 is turned on, the potential of the charge holding section 103 is reset to the potential of the power supply line Vdd. The selection transistor 214 controls an output timing of the pixel signal from the pixel circuit 210. The amplification transistor 213 generates a signal of a voltage corresponding to the level of the charge held in the charge holding section 103 as a pixel signal. The amplification transistor 213 is connected to the vertical signal line 543 via the selection transistor 214. The amplification transistor 213 constitutes a source follower together with a load circuit section (refer to FIG. 1) connected to the vertical signal line 543 in the column signal processing section 550. When the selection transistor 214 is turned on, the amplification transistor 213 outputs the voltage of the charge holding section 103 to the column signal processing section 550 via the vertical signal line 543. The reset transistor 211, the amplification transistor 213, and the selection transistor 214 are n-channel MOS transistors, for example.

The capacitance switching transistor 212 is used to change a gain of charge-voltage conversion in the charge holding section 103. In general, a pixel signal is weak at the time of photographing in a dark place. Based on Q=CV, when the capacitance (FD capacitance C) of the charge holding section 103 is large at the time of performing charge-voltage conversion, this results in a small V at the time of conversion into a voltage by the amplification transistor 213. On the other hand, in a bright place, the pixel signal becomes large, and thus, the charge holding section 103 cannot receive the charge of the photoelectric conversion section 101 unless the FD capacitance C is large. Further, the FD capacitance C needs to be large so that V when converted into a voltage by the amplification transistor 213 does not become too high (in other words, so as to be low). In view of these, when the capacitance switching transistor 212 is turned on, the gate capacitance for the capacitance switching transistor 212 increases, leading to a large entire FD capacitance C. In contrast, turning off the capacitance switching transistor 212 decreases the entire FD capacitance C. In this manner, switching on/off of the capacitance switching transistor 212 can achieve variable FD capacitance C, making it possible to switch the conversion efficiency. The capacitance switching transistor 212 is an re-channel MOS transistor, for example.

Incidentally, it is also possible to have a configuration not including the capacitance switching transistor 212. At this time, for example, the pixel circuit 210 includes three transistors, for example, an amplification transistor 213, a selection transistor 214, and a reset transistor 211. The pixel circuit 210 includes, for example, at least one of pixel transistors such as an amplification transistor 213, a selection transistor 214, a reset transistor 211, and a capacitance switching transistor 212.

The selection transistor 214 may be provided between the power supply line Vdd and the amplification transistor 213. In this case, the drain of the reset transistor 211 is electrically connected to the power supply line Vdd and the drain of the selection transistor 214. The source of the selection transistor 214 is electrically connected to the drain of the amplification transistor 213, while the gate of the selection transistor 214 is electrically connected to the row drive signal line 542 (refer to FIG. 1). The source of the amplification transistor 213 (an output end of the pixel circuit 210) is electrically connected to the vertical signal line 543, while the gate of the amplification transistor 213 is electrically connected to the source of the reset transistor 211. Note that, although not depicted, the number of pixels 541 sharing one pixel circuit 210 may be other than four. For example, two or eight pixels 541 may share one pixel circuit 210. [Configuration of pixel sharing unit]

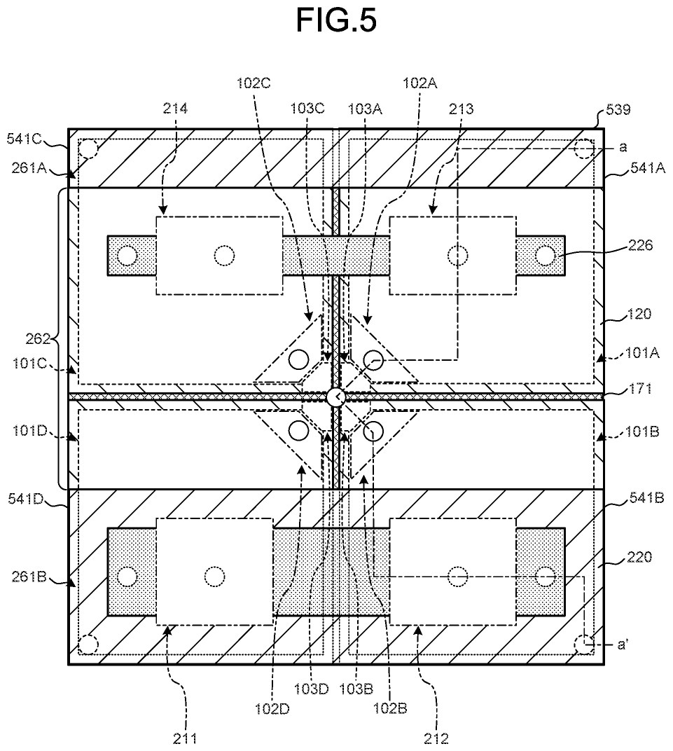

FIG. 5 is a diagram depicting a configuration example of a pixel sharing unit according to the embodiment of the present disclosure. The drawing is a plan view depicting a configuration example of the pixel sharing unit 539. In addition, FIG. 5 is a diagram depicting configurations of the first substrate 100 and the second substrate 200 viewed from the side of the second substrate 200.

In the drawing, regions with diagonal hatching represent regions of the semiconductor substrates (a first semiconductor substrate 120 and a second semiconductor substrate 220). A dotted polygon represents a semiconductor region formed on the first semiconductor substrate 120. A region with net hatching represents an isolating section (isolating section 171) formed on the first semiconductor substrate 120. A region with dot hatching represents a semiconductor region formed on the second semiconductor substrate 220. A two-dot chain line rectangle represents a gate electrode. A dotted circle represents a connecting location (connecting location 151) that connects the well region of the first semiconductor substrate 120 and the well region of the second semiconductor substrate 220 to each other. A dashed circle represents a contact plug (contact plug 244) formed on the second semiconductor substrate 220. A solid circle represents through-substrate electrodes (through-substrate electrodes 252 and 253).

As described above, the pixels 541A, 541B, 541C, and 541D are disposed on the first substrate 100. As depicted in the figure, the pixels 541A, 541B, 541C, and 541D are disposed in a 2 row×2 column pattern, and the charge holding sections 103A, 103B, 103C, and 103D are disposed in the vicinity of the central portions thereof. The charge transfer sections 102A, 102B, 102C, and 102D and the photoelectric conversion sections 101A, 101B, 101C, and 101D are disposed adjacent to the charge holding sections 103A, 103B, 103C, and 103D, respectively.

The pixel circuit 210 is disposed on the second substrate 200. The reset transistor 211 and the capacitance switching transistor 212 are disposed adjacent to each other, and the amplification transistor 213 and the selection transistor 214 are disposed adjacent to each other. The figure depicts an example in which the reset transistor 211 and the capacitance switching transistor 212 are disposed in a region overlapping the pixels 541D and 541B, respectively, while the amplification transistor 213 and the selection transistor 214 are disposed at positions overlapping the pixels 541A and 541C, respectively. Note that the amplification transistor 213 and the selection transistor 214 are formed in a semiconductor region 226 disposed in the same layer as the second semiconductor substrate 220.

The reset transistor 211 and the capacitance switching transistor 212 are disposed in a well region of the second semiconductor substrate 220 included in the semiconductor layer 200S described above. The reset transistor 211 in the drawing is provided with a drain region formed on the left side of the gate electrode and provided with a source region formed on the right side of the gate electrode. The source region of the reset transistor 211 also corresponds to the drain region of the capacitance switching transistor 212. The gate electrode and the source region are sequentially disposed adjacent to the drain region of the capacitance switching transistor 212.

An element isolating region 261 (element isolating region 261B) is disposed around the reset transistor 211 and the capacitance switching transistor 212. The element isolating region 261, which is a groove-shaped region formed on the front surface side of the second semiconductor substrate 220, isolates the diffusion layer of the element disposed on the second semiconductor substrate 220. The element isolating regions 261 allow adjacent elements to be isolated from each other while sharing the reference potential. In the element isolating region 261, the connecting location 151 is disposed. The drawing depicts the element isolating regions 261A and 261B.

The amplification transistor 213 and the selection transistor 214 are disposed separately from the reset transistor 211 and the capacitance switching transistor 212. The amplification transistor 213 is provided with a drain region formed on the right side of the gate electrode and provided with a source region formed on the left side of the gate electrode. The source region of the amplification transistor 213 also corresponds to the drain region of the selection transistor 214. The gate electrode and the source region are sequentially disposed adjacent to the drain region of the selection transistor 214.

By removing the second semiconductor substrate 220, a substrate isolating region 262 is formed to be disposed around the amplification transistor 213 and the selection transistor 214. By disposing the substrate isolating region 262, the amplification transistor 213 and the selection transistor 214 can be insulated from the reset transistor 211 and the like.

[Configuration of Cross-Section of Imaging Device]

FIG. 6 is a cross-sectional view depicting a configuration example of the imaging device according to the embodiment of the present disclosure. The figure is a cross-sectional view depicting a configuration example of the imaging device 1, and is a cross-sectional view taken along line a-a′ in FIG. 5. The imaging device 1 in the drawing includes a first substrate 100, a second substrate 200, and a third substrate 300. As described above, the first substrate 100 includes the semiconductor layer 100S and the wiring layer 100T, the second substrate 200 includes the semiconductor layer 200S and the wiring layer 200T, and the third substrate 300 includes the semiconductor layer 300S and the wiring layer 300T. Further, the imaging device 1 further includes a color filter 181 and an on-chip lens 401.

The semiconductor layer 100S includes a first semiconductor substrate 120, insulating films 128 and 129, and an isolating section 171.

The first semiconductor substrate 120 is a semiconductor substrate on which the photoelectric conversion section 101 is disposed. The charge transfer section 102 and the charge holding section 103 are further disposed on the first semiconductor substrate 120 in the drawing. The drawing depicts the photoelectric conversion sections 101A and 101B, the charge transfer sections 102A and 102B, and the charge holding sections 103A and 103B. The first semiconductor substrate 120 can be formed of silicon (Si), for example. The photoelectric conversion section 101 and the like are disposed in a well region formed in the first semiconductor substrate 120. For convenience, it is assumed that the first semiconductor substrate 120 in the drawing constitutes a p-type well region. By disposing an n-type semiconductor region in the p-type well region, an element (a diffusion layer of element) can be formed.

A rectangle described in the first semiconductor substrate 120 in the drawing represents an n-type semiconductor region. The photoelectric conversion section 101A is constituted with an n-type semiconductor region 121A. Specifically, a photodiode, constituted by a p-n junction formed at an interface between the n-type semiconductor region 121A and the surrounding p-type well region, corresponds to the photoelectric conversion section 101A. As depicted in the drawing, the photoelectric conversion section 101A is formed closer to the back surface side of the first semiconductor substrate 120. The photoelectric conversion section 101B is constituted similarly to the photoelectric conversion section 101A.

The charge holding sections 103A and 103B are constituted with n-type semiconductor regions 122A and 122B, respectively. These n-type semiconductor regions 122A and 122B constitute the above-described FD.

The charge transfer section 102A is constituted with the semiconductor regions 121A and 122A and a gate electrode 131A. The n-type semiconductor regions 121A and 122A correspond to the source region and the drain region of the charge transfer section 102A. As depicted in the drawing, the n-type semiconductor region 121A is formed closer to the back surface side of the first semiconductor substrate 120, while the n-type semiconductor region 122A is formed on front-side surface of the first semiconductor substrate 120. The gate electrode 131A includes a columnar portion disposed on the front surface side of the first semiconductor substrate 120 and having a depth reaching the n-type semiconductor region 121A. When a drive voltage is applied to the gate electrode 131A, a channel is formed in a well region adjacent to the gate electrode 131A, allowing the n-type semiconductor regions 121A and 122A to be conductive. That is, conduction is established between the photoelectric conversion section 101A and the charge holding section 103A, allowing the charge of the photoelectric conversion section 101A to be transferred to the charge holding section 103A. In this manner, the charge transfer section 102A is constituted with a vertical transistor that transfers a charge in the thickness direction of the semiconductor substrate.

Similarly to the charge transfer section 102A, the charge transfer section 102B includes semiconductor regions 121B and 122B and a gate electrode 131B. The gate electrodes 131A and 131B can be formed with polycrystalline silicon implanted with impurities.

Note that semiconductor regions 123A and 123B are disposed on the first semiconductor substrate 120. The semiconductor regions 123A and 123B, being semiconductor regions disposed in the well region of the first semiconductor substrate 120, are semiconductor regions having the same conductivity type as the well region and formed to have a relatively high impurity concentration.

The insulating film 129 is a film that insulates the front surface side of the first semiconductor substrate 120. Further, the insulating film 128 is a film that insulates the back surface side of the first semiconductor substrate 120. These films can be formed with silicon oxide (SiO₂) or silicon nitride (SiN). The insulating film 129 is also disposed between the gate electrodes 131A and 131B and the first semiconductor substrate 120. The insulating film 129 corresponds to a gate oxide film.

The isolating section 171 is disposed at a boundary of the pixels 541 to isolate the pixels 541 from each other. The drawing depicted an example in which the pixels 541A and 541B are isolated from each other by the isolating section 171. The isolating section 171 can be constituted by embedding an insulator such as SiO₂ in a groove portion penetrating from the back surface side to the front surface side of the first semiconductor substrate 120.

The wiring layer 100T includes an insulating layer 141, a pad 132, and connecting locations 151A and 151B. The insulating layer 141 insulates the gate electrode 131, the pad 132, and the like disposed on the front surface side of the first semiconductor substrate 120. The insulating layer 141 can be formed of SiO₂, for example. The pad 132 is an electrode connected to the charge holding sections 103A and 103B and the charge holding sections 103C and 103D (not depicted). The pad 132 is further connected to a through-substrate electrode 252 described below. The pad 132 can be formed with polycrystalline silicon implanted with impurities.

The connecting locations 151A and 151B connect the first semiconductor substrate 120 and the second semiconductor substrate 220 in order to allow the reference potential (well potential) of the first semiconductor substrate 120 and the second semiconductor substrate 220 to be used in common. The connecting location 151A is disposed between the semiconductor region 123A and a high impurity concentration region 225A to be described below, while the connecting location 151B is disposed between the semiconductor region 123B and a high impurity concentration region 225B to be described below. The connecting locations 151A and 151B can be formed with polycrystalline silicon implanted with impurities. Note that the connecting locations 151A and 151B are also referred to as well contacts.

The semiconductor layer 200S includes a second semiconductor substrate 220, a semiconductor region 226, an element isolating region 261, a high impurity concentration region 225, and an insulating film 229.

The second semiconductor substrate 220 is a semiconductor substrate on which the pixel circuit 210 is disposed. In the drawing, the capacitance switching transistor 212 and the amplification transistor 213 of the pixel circuit 210 are depicted as being disposed on the second semiconductor substrate 220. Similarly to the first semiconductor substrate 120, the second semiconductor substrate 220 can be formed of Si. In addition, similarly to the first semiconductor substrate 120, a p-type well region is formed in the second semiconductor substrate 220. For convenience, it is assumed that the second semiconductor substrate 220 in the drawing constitutes a p-type well region.

The capacitance switching transistor 212 includes n-type semiconductor regions 221 and 222 and a gate electrode 231. As described above, the capacitance switching transistor 212 is isolated by the element isolating region 261 (element isolating region 261B). As depicted in the drawing, the element isolating region 261B is formed in a groove shape having a depth that isolates a region where a diffusion layer (n-type semiconductor region 221 or the like) formed on the front surface side of the second semiconductor substrate 220 is formed. Note that the element isolating region 261 is a region in which an insulating layer 241 to be described below is disposed.

The amplification transistor 213, being formed in the semiconductor region 226, is constituted with: a semiconductor region (not depicted) constituting a drain region and a source region; and a gate electrode 232. As described above, the semiconductor region 226 where the amplification transistor 213 is formed is isolated from the second semiconductor substrate 220 by the substrate isolating region 262. The substrate isolating region 262 is an isolating region formed by removing the second semiconductor substrate 220. The insulating layer 241 to be described below is also disposed in the substrate isolating region 262.

The high impurity concentration region 225 is a semiconductor region disposed at the bottom of the element isolating region 261 and configured to have a relatively high impurity concentration of the same conductivity type as the well region of the second semiconductor substrate 220. The drawing depicts the high impurity concentration regions 225A and 225B.

The wiring layer 200T includes an insulating layer 241, a wiring line 242, a via plug 243, a contact plug 244, through-substrate electrodes 252, 253A, and 253B, second connecting locations 251A and 251B, and contact sections 201 and 202. The wiring line 242 is a conductor that transmits an electric signal or the like to an element or the like disposed on the second semiconductor substrate 220. The wiring line 242 can be formed of metal such as copper (Cu). The insulating layer 241 insulates the wiring line 242 and the like. Similarly to the insulating layer 141, the insulating layer 241 can be formed of SiO₂ or the like. The wiring line 242 and the insulating layer 241 can be configured in multiple layers. The drawing depicts the wiring line 242 and the insulating layer 241 configured in three layers as an example. The wiring lines 242 disposed in different layers can be connected to each other by the via plug 243. The via plug 243 can be formed of columnar metal such as columnar Cu, for example. In addition, the wiring line 242 and the semiconductor region 222, the gate electrode 231, and the like of the second semiconductor substrate 220 can be connected by the contact plug 244. The contact plug 244 can be formed of a columnar metal such as a columnar W, for example.

The through-substrate electrode 252 and the like are columnar electrodes that connect the wiring line 242 and a member disposed on the front surface side of the first semiconductor substrate 120. The through-substrate electrode 252 is connected to the pad 132. The through-substrate electrodes 253A and 253B are connected to the gate electrodes 131A and 131B, respectively. These through-substrate electrodes 252 and the like can be formed of metal such as W, and can be disposed in the substrate isolating region 262.

The second connecting locations 251A and 251B connect the second semiconductor substrate 220 and a third semiconductor substrate 320 in order to allow the reference potential to be used in common with another circuit, for example, a circuit disposed on the third substrate 300. The second connecting locations 251A and 251B can be formed of a columnar W, for example. Note that the second connecting locations 251A and 251B in the drawing are connected to the third substrate 300 via the wiring line 242, the via plug 243, and the contact section 201.

As described above, the contact sections 201 and 202 are connected to the contact sections 301 and 303 of the third substrate 300, respectively. The contact section 201 is connected to the second connecting location 251 and transmits the reference potential. The contact section 202 is used to transmit signals and the like.

The semiconductor layer 300S includes the third semiconductor substrate 320. The above-described image signal processing section 560 (not depicted) and the like are disposed on the third semiconductor substrate 320. In addition, a well region is formed in the third semiconductor substrate 320. A semiconductor region 321 is disposed in this well region. Similarly to the semiconductor region 123, the semiconductor region 321 is formed to have a relatively high impurity concentration, and is connected to a contact plug 344.

The wiring layer 300T includes an insulating layer 341, a wiring 342, a via plug 343, a contact plug 344, and contact sections 301 and 302. Since these configurations are similar to the insulating layer 241, the wiring line 242, the via plug 243, the contact plug 244, and the contact sections 301 and 302, the description thereof will be omitted.

As depicted in the drawing, the second connecting location 251 is connected to the semiconductor region 321 of the third semiconductor substrate 320 via the wiring line 242, the via plug 243, the contact section 201, the contact section 301, the via plug 343, the wiring 342, and the contact plug 344. With this configuration, the well region of the second semiconductor substrate 220 is electrically connected with the well region of the third semiconductor substrate 320, allowing the reference potential to be used in common. The reference potential can be obtained by applying a ground potential of a power supply circuit connected to the third semiconductor substrate 320, for example. In addition, a fixed potential other than the ground potential is also applicable to the reference potential. In this manner, the reference potential is supplied to the second semiconductor substrate 220 via the second connecting location 251.

The color filter 181 is an optical filter that is disposed for each pixel 541 and transmits light having a predetermined wavelength among the incident light. The on-chip lens 401 is a lens that is disposed for each pixel 541 and condenses incident light onto the photoelectric conversion section 101. [Configuration of pixel sharing unit]

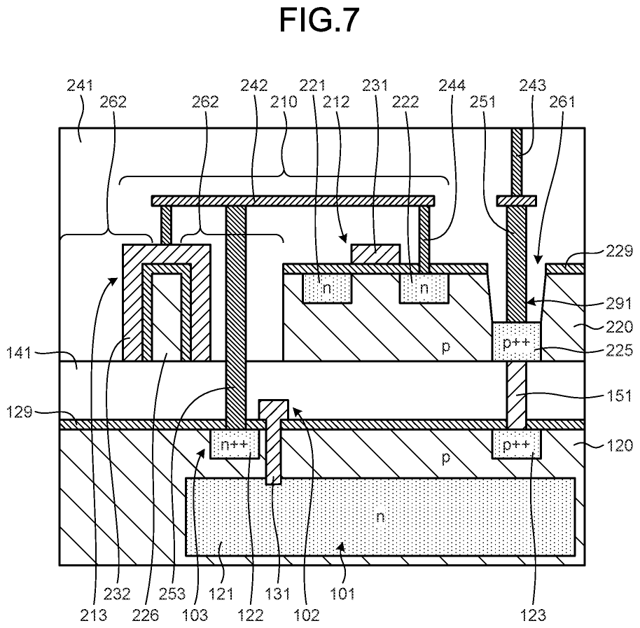

FIG. 7 is a diagram depicting a configuration example of a pixel sharing unit according to the first embodiment of the present disclosure. The drawing is a schematic cross-sectional view depicting a configuration example of the first semiconductor substrate 120 and the second semiconductor substrate 220 including the connecting location 151 in the pixel sharing unit 539. The drawing depicts some of the component in the cross-sectional view of FIG. 6, specifically, elements of the photoelectric conversion section 101, the charge transfer section 102, the charge holding section 103, and the pixel circuit 210, together with the semiconductor region 123, the high impurity concentration region 225, the connecting location 151, and the second connecting location 251. Note that the capacitance switching transistor 212 and the amplification transistor 213 are depicted as the pixel circuit 210, without depicting the reset transistor 211 or the selection transistor 214.

The photoelectric conversion section 101 is connected to the charge holding section 103 via the charge transfer section 102 which is a vertical transistor. The charge holding section 103 is connected to the wiring line 242 by the through-substrate electrode 253. A source region of the capacitance switching transistor 212 and a gate electrode of the amplification transistor 213 are connected to the wiring line 242 via the contact plug 244.

The capacitance switching transistor 212 and the reset transistor 211 (not depicted), which are constituted as planar type MOS transistors, are formed in a well region of the second semiconductor substrate 220. The capacitance switching transistor 212 and the reset transistor 211 are isolated from the capacitance switching transistor 212 and the reset transistor 211 of the adjacent pixel sharing unit 539 by the element isolating region 261. The capacitance switching transistor 212 and the reset transistor 211 disposed in different pixel sharing units 539 are connected via a well region, and operate on the basis of a common reference potential (well potential).

On the other hand, the amplification transistor 213 and the selection transistor 214 (not depicted) are constituted in a shape in which the gate electrode 232 is disposed on three sides of the semiconductor region 226 having a cuboid shape, via the insulating film 229. The amplification transistor 213 having such a shape is referred to as a fin FET (Fin FET). Further, the amplification transistor 213 and the like are MOS transistors that operate in a depletion mode. In order to achieve complete depletion of the amplification transistor 213, the semiconductor region 226 is constituted to have a relatively low impurity concentration. In addition, the amplification transistor 213 and the selection transistor 214 are isolated and insulated from the second semiconductor substrate 220 on which the capacitance switching transistor 212 and the like are disposed by the substrate isolating region 262. This allows the amplification transistor 213 and the selection transistor 214 to have floating potentials different from the reference potential of the second semiconductor substrate 220.

As described below, the semiconductor region 226 is formed by isolating a part of the second semiconductor substrate 220 by the substrate isolating region 262. Note that the semiconductor region 226 is an example of a semiconductor region described in the claims.

The semiconductor region 123 is disposed in the well region of the first semiconductor substrate 120. As described above, the semiconductor region 123 is configured to have a relatively high impurity concentration of the same conductivity type as the well region. The well region of the first semiconductor substrate 120 is connected to the connecting location 151 for allowing the reference potential (well potential) to be used in common. These semiconductor regions 123 are semiconductor regions disposed to make ohmic connection between the connecting location 151 and the well region of the first semiconductor substrate 120.

The high impurity concentration region 225 is disposed in the well region of the element isolating region 261 of the second semiconductor substrate 220. The high impurity concentration region 225 is connected, on its back surface side, to the connecting location 151 and connected, on its front surface side, to the second connecting location 251. As described above, the high impurity concentration region 225 is configured to have the same conductivity type as the well region, with a relatively high impurity concentration, for example, an impurity concentration of 5×10¹⁷ cm⁻³ or more. By disposing the high impurity concentration region 225, the connection between the connecting location 151 and the second connecting location 251 and the well region of the second semiconductor substrate 220 can be achieved as ohmic connection. In addition, the resistance of the high impurity concentration region 225 can be reduced, making it possible to reduce the voltage drop in the high impurity concentration region 225.

As depicted in the drawing, the second connecting location 251 is connected to the well region of the first semiconductor substrate 120 via the high impurity concentration region 225 and the connecting location 151. The second connecting location 251 can be formed by embedding a metal such as W in an opening 291 formed in the insulating layer 241.

As described above, the second connecting location 251 is connected to the circuit of the third semiconductor substrate 320 via the wiring line 242 or the like, and supplies the reference potential. A common reference potential is supplied to the well region of the second semiconductor substrate 220 and the well region of the first semiconductor substrate 120 connected to each other by the second connecting location 251 and the connecting location 151. In this case, the well region of the first semiconductor substrate 120 and the well region of the second semiconductor substrate 220 are configured to have the same conductivity type. In an example of the drawing, the well region of the first semiconductor substrate 120 and the well region of the second semiconductor substrate 220 are configured to be p-type. Such a well region is referred to as a p-well. A reference potential corresponding to the lowest voltage of the signal voltage and the power supply voltage is applied to such a p-well. For example, the ground potential is supplied to the second connecting location 251. This ground potential can be supplied via a ground line of a power supply circuit that supplies power to the imaging device 1, for example. This ground line normally has a potential of 0 V.

In addition, by disposing the high impurity concentration region 225 at the bottom of the element isolating region 261 and connecting the connecting location 151 and the second connecting location 251 to the second semiconductor substrate 220 in the element isolating region 261, it is possible to reduce the area of the second semiconductor substrate 220. In addition, by disposing the high impurity concentration region 225 only on the bottom of the element isolating region 261, it is possible, in the manufacturing steps, to isolate a region where impurities diffuse from the element isolating region 261, from elements such as the capacitance switching transistor 212.

As described above, the amplification transistor 213 and the selection transistor 214 operate in the depletion mode. In contrast, the capacitance switching transistor 212 operates in an enhancement mode. Therefore, the amplification transistor 213 and the selection transistor 214 can be configured to have an impurity concentration different from the concentration of the well region in which the capacitance switching transistor 212 and the like are disposed.

The high impurity concentration region 225 in the drawing is formed in a region ranging from the bottom of the element isolating region 261 to the back surface side of the second semiconductor substrate 220. The configuration of the high impurity concentration region 225 is not limited to this example. For example, a high impurity concentration region can be disposed on each of the bottom portion of the element isolating region 261 and the back surface side of the second semiconductor substrate 220. In this case, the well region is disposed between the respective high impurity concentration regions.

[Method of Manufacturing Pixel Array Section]

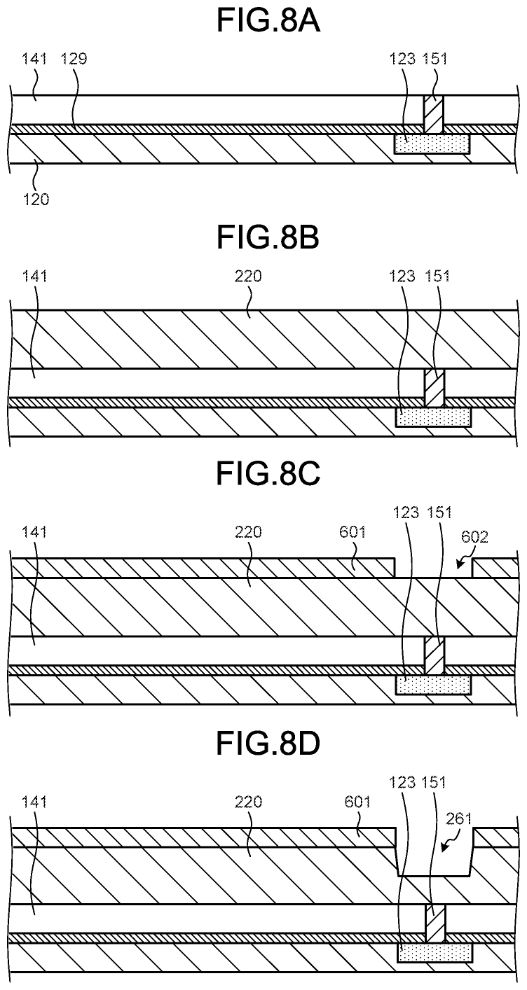

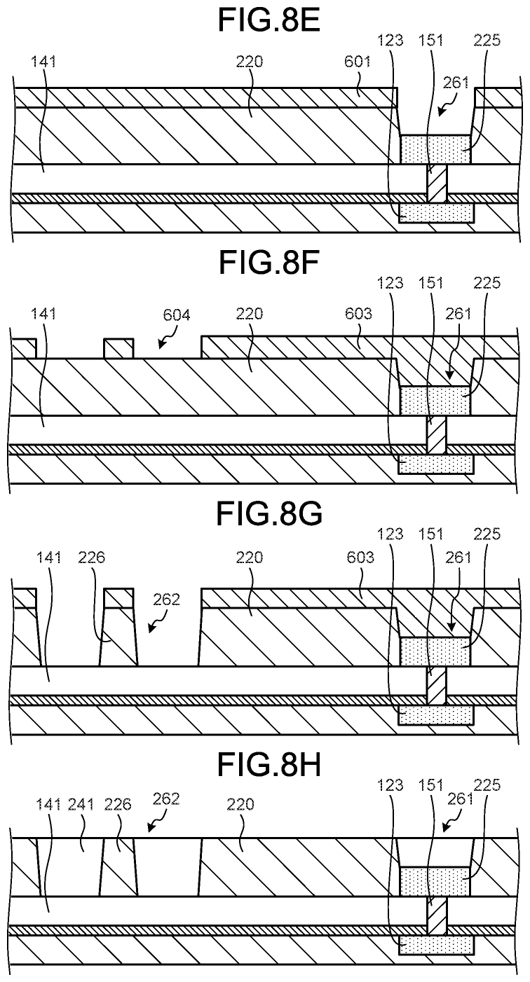

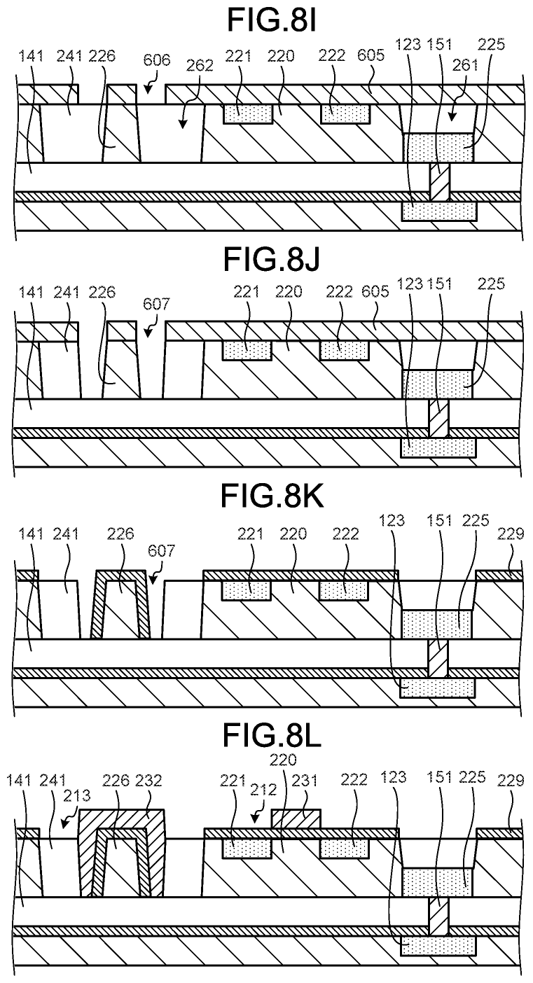

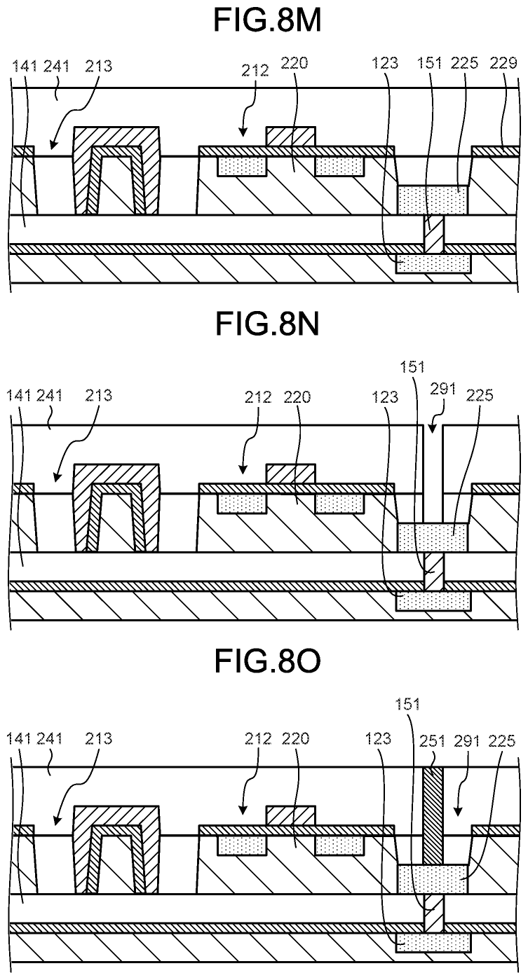

FIGS. 8A to 8L are diagrams each depicting an example of a method of manufacturing the pixel array section according to the first embodiment of the present disclosure. FIGS. 8A to 8L are diagrams depicting a step of forming the connecting location 151, the second connecting location 251, and elements of the second semiconductor substrate 220 in the manufacturing step of the pixel array section 540.

First, a well region is formed in the first semiconductor substrate 120 to form the semiconductor region 123 and the like. Next, the insulating film 129 is disposed on the front-side surface of the first semiconductor substrate 120. Next, the insulating layer 141 is disposed on the front surface side of the first semiconductor substrate 120. This process can be performed by forming a film of SiO₂ or the like by a method such as chemical vapor deposition (CVD). Next, an opening is formed in the insulating layer 141 adjacent to the semiconductor region 123. The connecting location 151 is disposed in the opening. This process can be performed by forming a film of polycrystalline silicon or the like using a method such as CVD and removing an excessive film (FIG. 8A).

Next, the second semiconductor substrate 220 is stacked on the front surface side of the first semiconductor substrate 120. This process can be performed by heating and pressing the first semiconductor substrate 120 and the second semiconductor substrate. Next, the second semiconductor substrate 220 is ground to a desired thickness (FIG. 8B).

Next, a hard mask 601 is disposed on the front surface side of the second semiconductor substrate 220. On the hard mask 601, an opening 602 is disposed in a region where the element isolating region 261 is to be formed (FIG. 8C).

Next, the second semiconductor substrate 220 in the opening 602 of the hard mask 601 is etched to form the element isolating region 261. This process can be performed by dry etching, for example (FIG. 8D).

Next, ion implantation of impurities such as boron (B), for example, is performed using the hard mask 601 as a mask to form the high impurity concentration region 225 (FIG. 8E).

Next, after removing the hard mask 601, a hard mask 603 is disposed. On the hard mask 603, an opening 604 is disposed in a region where the substrate isolating region 262 is to be formed (FIG. 8F).

Next, the second semiconductor substrate 220 in the opening 604 of the hard mask 603 is etched to form the substrate isolating region 262 (FIG. 8G).

Next, the hard mask 603 is removed. Next, the insulating layer 241 is disposed on the front surface side of the second semiconductor substrate 220 including the element isolating region 261 and the substrate isolating region 262. Next, the front surface side of the second semiconductor substrate 220 is ground, and the insulating layer 241 disposed in a region other than the element isolating region 261 and the substrate isolating region 262 is removed (FIG. 8H). This process can be performed by chemical mechanical polishing (CMP).

Next, the semiconductor region 221 and the like are formed on the second semiconductor substrate 220. This can be formed by disposing a resist having an opening in a region such as the semiconductor region 221 on the front surface side of the second semiconductor substrate 220 and performing ion implantation. Next, a hard mask 605 is disposed on the front surface side of the second semiconductor substrate 220. In the hard mask 605, an opening 606 is disposed in a region where the gate electrode 232 is to be formed (FIG. 8I).

Next, the second semiconductor substrate 220 in the opening 606 of the hard mask 605 is etched to form an opening 607 (FIG. 8J).

Next, the hard mask 605 is removed. Next, the insulating film 229 is disposed on the front-side surface of the second semiconductor substrate 220 (FIG. 8K).

Next, the gate electrodes 231 and 232 are disposed. This process can be performed by forming a material film such as the gate electrode 231 on the front surface side of the second semiconductor substrate 220 including the opening 607 and removing a film of an unnecessary region (FIG. 8L).

Next, the insulating layer 241 is stacked on the front surface side of the second semiconductor substrate 220 (FIG. 8M). Next, the opening 291 is formed in the insulating layer 241 adjacent to the element isolating region 261 (N of FIG. 8N). This can be formed by disposing a resist having an opening in a region where the opening 291 is to be formed and performing dry etching, for example.

Next, the second connecting location 251 is disposed in the opening 291 (FIG. 8O). This process can be performed by disposing a material film of the second connecting location 251 on the front surface side of the second semiconductor substrate 220 including the opening 291 and grinding an unnecessary film by CMP or the like.

Thereafter, the formation of the wiring line 242 and the formation of the insulating layer 241 is repeated for a desired number of layers to form the wiring layer 200T. Thereafter, the third semiconductor substrate 320 is stacked.

Through the above steps, the connecting location 151, the second connecting location 251, and elements of the second semiconductor substrate 220 can be formed.

In this manner, in the imaging device 1 according to the first embodiment of the present disclosure, the high impurity concentration region 225 is disposed in the element isolating region 261 formed in the second semiconductor substrate 220, and the connecting location 151 is connected for allowing the reference potential to be used in common with the first semiconductor substrate 120. With this configuration, the region where the connecting location 151 is disposed can be disposed to overlap the region of the element isolating region 261, making it possible to reduce the area of the second semiconductor substrate 220. In addition, by disposing the second connecting location 251 in the high impurity concentration region 225, it is possible to further reduce the area of the second semiconductor substrate 220.

### 2. Second Embodiment

The imaging device 1 of the first embodiment described above includes the second connecting location 251 formed of metal. In contrast, an imaging device 1 according to a second embodiment of the present disclosure is different from the above-described first embodiment in that the imaging device 1 includes a second connecting location 251 formed of Si.

[Configuration of Pixel Sharing Unit]

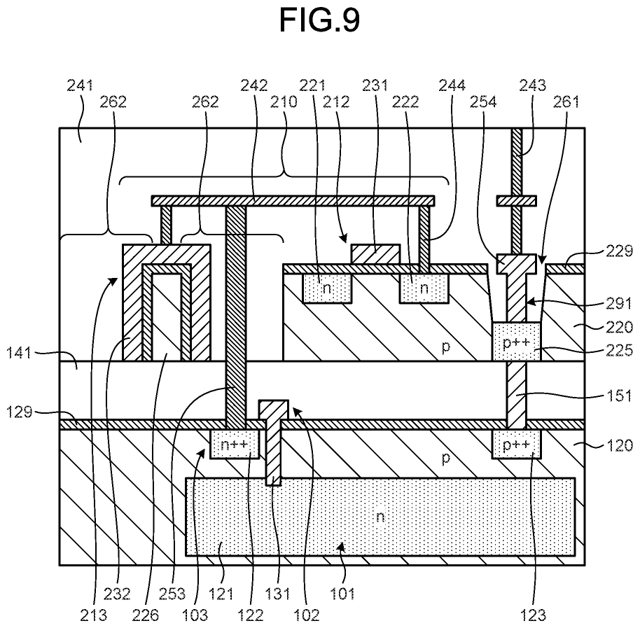

FIG. 9 is a diagram depicting a configuration example of a pixel sharing unit according to the second embodiment of the present disclosure. The figure, similarly to FIG. 7, is a schematic cross-sectional view depicting a configuration example of the first semiconductor substrate 120 including the connecting location 151 and the second semiconductor substrate 220 in the pixel sharing unit 539. The imaging device in the drawing is different from the pixel sharing unit 539 in FIG. 7 in including a second connecting location 254 instead of the second connecting location 251.

Similarly to the connecting location 151, the second connecting location 254 is a connecting location formed of polycrystalline silicon. Note that the resistance of the polycrystalline silicon constituting the second connecting location 254 can be reduced by implanting impurities such as B, for example.

[Method for Manufacturing Connecting Location]

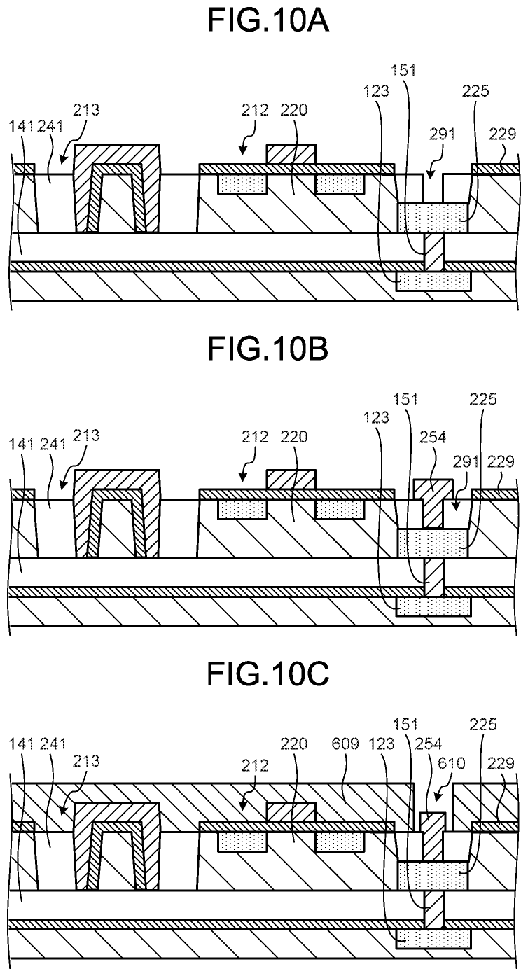

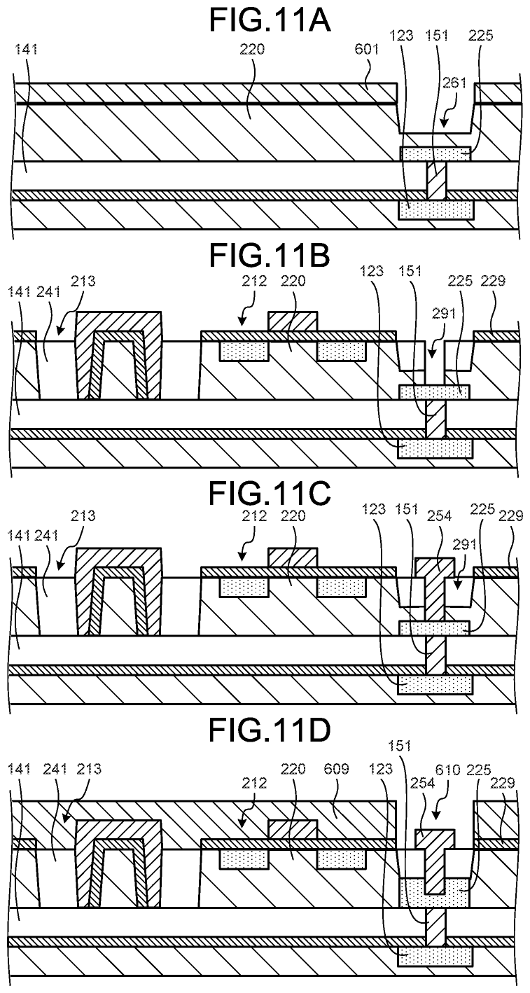

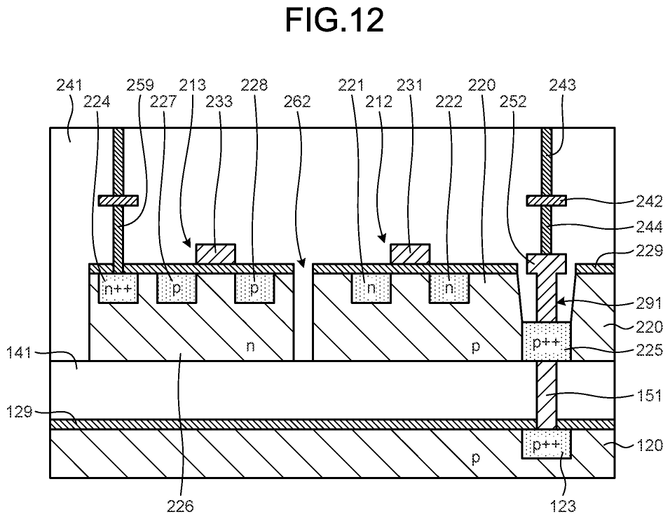

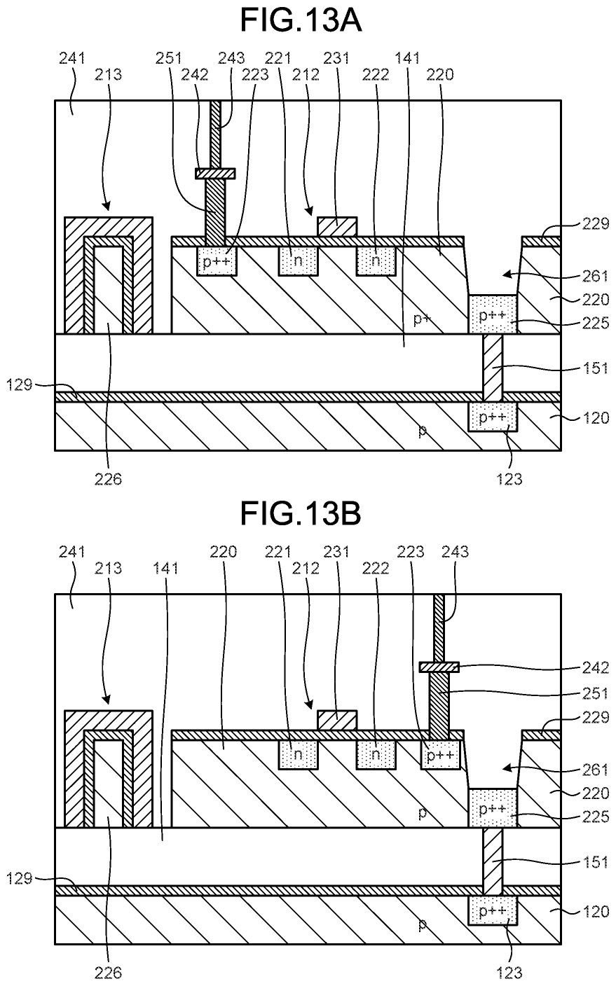

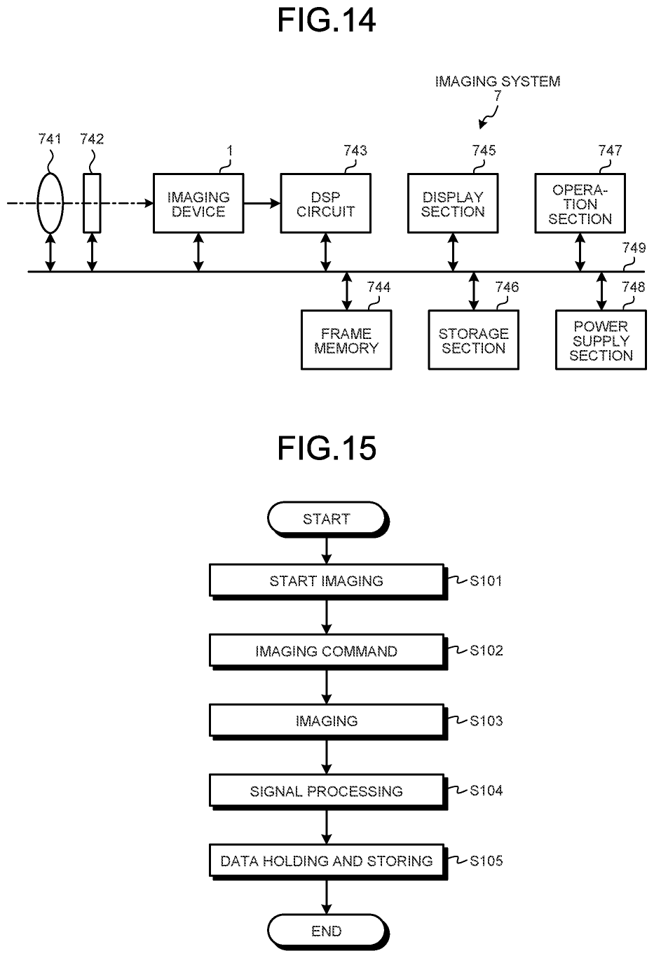

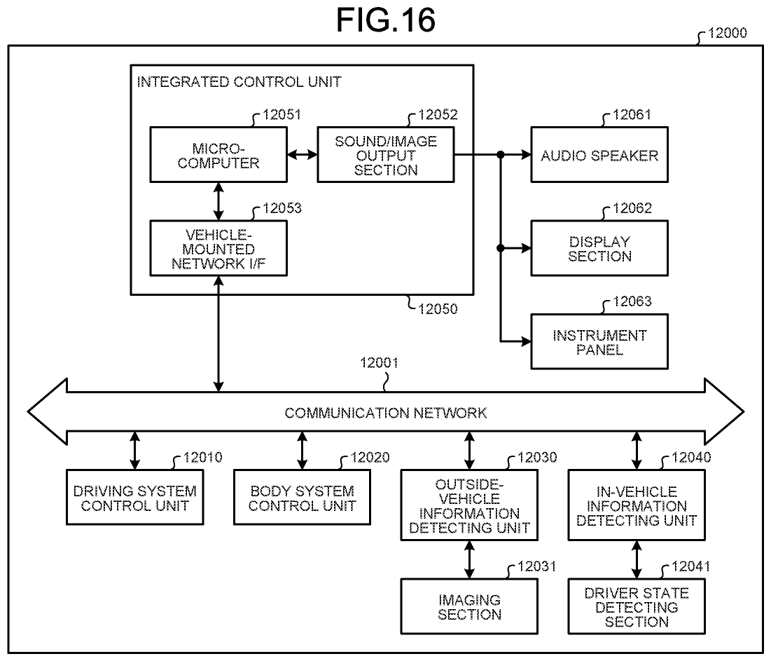

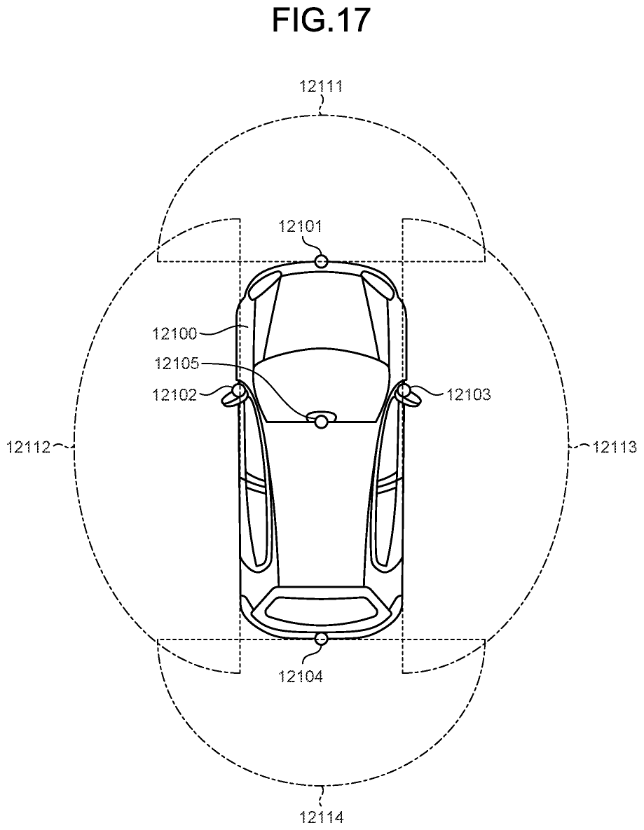

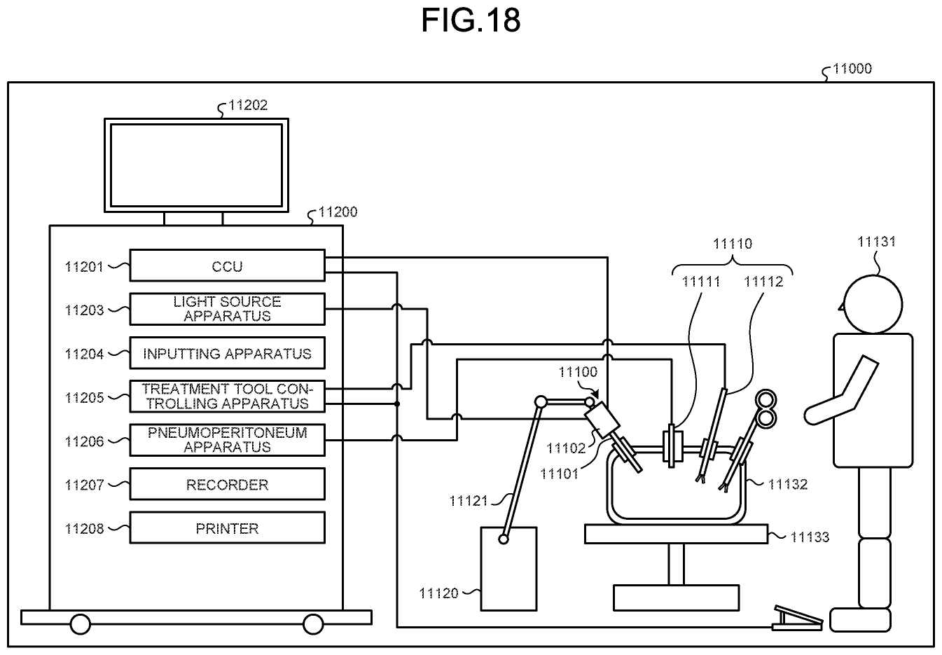

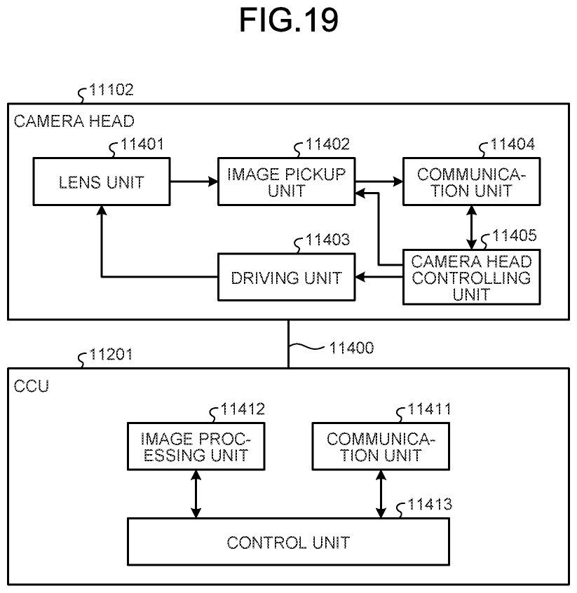

FIGS. 10A to 10C are diagrams depicting an example of a method of manufacturing the second connecting location according to the second embodiment of the present disclosure. FIGS. 10A to 10C are diagrams depicting an example of manufacturing steps of the second connecting location 254.

First, the steps of FIGS. 8A to 8L are executed. Next, an opening 291 is formed in the insulating layer 241 disposed in the element isolating region 261 (FIG. 10A).

Next, the second connecting location 254 is disposed in the opening 291 (FIG. 10B). This process can be performed by forming a polycrystalline silicon film on the front surface side of the second semiconductor substrate 220 including the opening 291 and removing an unnecessary film.

Next, a resist 609 is disposed on the front surface side of the second semiconductor substrate 220. The resist 609 has an opening 610 in the vicinity of the second connecting location 254 (FIG. 100). Next, ion implantation of B is performed using the resist 609 as a mask. This process can reduce the resistance of the second connecting location 254.

[Another Method for Manufacturing Connecting Location]

FIGS. 11A to 11D are diagrams depicting another example of the method of manufacturing the second connecting location according to the second embodiment of the present disclosure. First, the steps of FIGS. 8A to 8D are executed. Next, impurities such as B included in the connecting location 151 are diffused into the second semiconductor substrate 220 adjacent to the connecting location 151 to form the high impurity concentration region 225 (FIG. 11A). This process can be performed by thermal diffusion. Next, the steps of FIGS. 8E to 8L are executed to dispose the insulating layer 241 in the element isolating region 261. Next, an opening 291 is formed in the insulating layer 241 and the second semiconductor substrate 220 (FIG. 11B).

Next, similarly to the steps of FIG. 10B, the second connecting location 254 is disposed in the opening 291 (FIG. 11C).

Next, the resist 609 described in FIG. 100 is disposed on the front surface side of the second semiconductor substrate 220, and ion implantation of impurities is performed (FIG. 11D). This process can reduce the resistance of the second connecting location 254. At this time, ion implantation of B is also performed into the second semiconductor substrate 220 in the vicinity of the bottom of the second connecting location 254, and the high impurity concentration region 225 is also formed on the front surface side of the second semiconductor substrate 220.

The configuration of the imaging device 1 other than this is similar to the configuration of the imaging device 1 in the first embodiment of the present disclosure, and thus the description thereof will be omitted.

In this manner, in the imaging device 1 according to the second embodiment of the present disclosure, the reference potential is supplied to the second semiconductor substrate 220 and the first semiconductor substrate 120 by the second connecting location 254 formed of polycrystalline silicon into which impurities have been implanted.

### 3. Third Embodiment

The imaging device 1 of the first embodiment described above includes the fin FET isolated from the well region of the second semiconductor substrate 220. In contrast, an imaging device 1 according to a third embodiment of the present disclosure is different from the above-described first embodiment in that the imaging device 1 includes a MOS transistor formed in a well region to which a potential different from that of the well region of the second semiconductor substrate 220 is supplied.

[Configuration of Pixel Sharing Unit]

FIG. 12 is a diagram depicting a configuration example of a pixel sharing unit according to the third embodiment of the present disclosure. The figure, similarly to FIG. 7, is a schematic cross-sectional view depicting a configuration example of the first semiconductor substrate 120 including the connecting location 151 and the second semiconductor substrate 220 in the pixel sharing unit 539. The imaging device in the drawing is different from the pixel sharing unit 539 in FIG. 7 in that the amplification transistor 213 is constituted with a p-channel MOS transistor.

The amplification transistor 213 in the drawing is formed with a p-channel MOS transistor. The amplification transistor 213 is formed in a semiconductor region 226 constituted in an n-type well region. Specifically, p-type semiconductor regions 228 and 227 corresponding to the source region and the drain region, respectively, are disposed in the well region of the semiconductor region 226. A reference potential (well potential) different from the p-type well region in which the capacitance switching transistor 212 is disposed is supplied to the n-type well region. Specifically, the highest potential in a circuit such as a power supply line that supplies power is supplied as a reference potential to the n-type well region.

In this manner, since the reference potential is different from that of the second semiconductor substrate 220 constituted in the p-type well region, the semiconductor region 226 constituted in the n-type well region is isolated and insulated from the second semiconductor substrate 220. The semiconductor region 226 in the drawing is isolated from the second semiconductor substrate 220 in the drawing by a substrate isolating region 262. Such an n-type well region is also referred to as an n-well. The well region of the semiconductor region 226 can be formed by isolating the second semiconductor substrate 220 by the substrate isolating region 262 and adding an impurity such as phosphorus (P) by ion implantation.

In the well region of the semiconductor region 226, a semiconductor region 224 configured to have a high n-type impurity concentration is disposed. The semiconductor region 224 is connected with a contact plug 259. Through the contact plug 259, a reference potential is supplied from the third semiconductor substrate 320.

The imaging device 1 of the third embodiment is not limited to this example. For example, the semiconductor region 226 may be constituted as a p-type well region, and a reference potential having a potential different from that of the well region of the second semiconductor substrate 220 may be supplied. Specifically, when the ground potential is supplied as the reference potential of the well region of the second semiconductor substrate 220, a negative reference potential can also be supplied to the well region of the semiconductor region 226.

The configuration of the imaging device 1 other than this is similar to the configuration of the imaging device 1 in the first embodiment of the present disclosure, and thus the description thereof will be omitted.

In this manner, in the imaging device 1 according to the third embodiment of the present disclosure, a semiconductor element having the reference potential different from those of the first semiconductor substrate 120 and the second semiconductor substrate 220 can be disposed close to the second semiconductor substrate 220. This makes it possible to increase variations of elements applicable to the pixel sharing unit 539 and the like.

### 4. Fourth Embodiment

In the imaging device 1 of the first embodiment described above, the second connecting location 251 is disposed in the element isolating region 261. In contrast, an imaging device 1 according to a fourth embodiment of the present disclosure is different from the above-described first embodiment in that a second connecting location 251 is disposed in a region different from the element isolating region 261.

[Configuration of Pixel Sharing Unit]

FIG. 13A is a diagram depicting a configuration example of a pixel sharing unit according to the fourth embodiment of the present disclosure. The figure, similarly to FIG. 7, is a schematic cross-sectional view depicting a configuration example of the first semiconductor substrate 120 including the connecting location 151 and the second semiconductor substrate 220 in the pixel sharing unit 539. The pixel sharing unit 539 in the drawing is different from the pixel sharing unit 539 in FIG. 7 in that the second connecting location 251 is disposed in a region different from the element isolating region 261.

In the second semiconductor substrate 220 in the drawing, a semiconductor region 223 is disposed in a region different from the element isolating region 261. The semiconductor region 223 is a semiconductor region constituted to have a high p-type impurity concentration. The second connecting location 251 is connected to the semiconductor region 223. The reference potential is supplied via the second connecting location 251. By disposing the second connecting location 251 at a position different from the element isolating region 261, it is possible to easily form the second connecting location 251. Even with a narrowed width of the element isolating region 261, it is possible to reduce the occurrence of failures due to positional deviation of the second connecting location 251 or the like. Further, the figure depicts an example in which an element such as the capacitance switching transistor 212 is disposed between the second connecting location 251 and the connecting location 151.

On the other hand, since the second connecting location 251 and the connecting location 151 are disposed apart from each other. Therefore, in the pixel sharing unit 539 in the drawing, the electrical resistance between the second connecting location 251 and the connecting location 151 is relatively large. This increases the voltage drop between the second connecting location 251 and the connecting location 151, producing a potential difference in the well potential of the second semiconductor substrate 220. This leads to a possibility of affecting the operation of the capacitance switching transistor 212 and the like disposed between the second connecting location 251 and the connecting location 151.

In order to reduce the electrical resistance between the second connecting location 251 and the connecting location 151, it is necessary to increase the impurity concentration of the well region to reduce the resistance as depicted in the drawing. However, increasing the impurity concentration of the well region of the second semiconductor substrate 220 would increase impurities to be diffused from the region to the periphery. Arrival of this diffusing impurity at the semiconductor region 226 of the amplification transistor 213 would increase the impurity concentration of the semiconductor region 226, causing inhibition of depletion of the amplification transistor 213. This causes deterioration of the performance of the amplification transistor 213. In addition, in order to increase the impurity concentration in the well region of the second semiconductor substrate 220, it is necessary to perform ion implantation with a high dose and high energy. When such ion implantation is performed, impurity ions would be also implanted into the semiconductor region 226 close to the second semiconductor substrate 220, increasing and the impurity concentration of the semiconductor region 226.

This type of problem, such as diffusion of impurities from the second semiconductor substrate 220, is a problem that is likely to occur in the semiconductor region 226 described in FIG. 12.

FIG. 13B is a diagram depicting another configuration example of the pixel sharing unit according to the fourth embodiment of the present disclosure. The pixel sharing unit 539 in FIG. 13B is different from the pixel sharing unit 539 in FIG. 13A in that the second connecting location 251 and the semiconductor region 223 are disposed adjacent to the element isolating region 261.

The second connecting location 251 in FIG. 13B is disposed adjacent to the element isolating region 261. Since the second connecting location 251 is disposed in the vicinity of the connecting location 151, it is possible to reduce the electric resistance between the second connecting location 251 and the connecting location 151, leading to reduction of the voltage drop in the portion. In addition, since elements such as the capacitance switching transistor 212 are disposed at positions away from the second connecting location 251 and the connecting location 151, it is possible to reduce the influence of the voltage drop due to the semiconductor substrate between the second connecting location 251 and the connecting location 151. With this configuration, reference potentials (well potentials) of substantially the same potential are applied to the plurality of elements disposed in the well region of the second semiconductor substrate 220. This makes it possible, in the second semiconductor substrate 220 in the drawing, to set the impurity concentration in the well region be made relatively low. It is not necessary to reduce the resistance of the well region described in FIG. 13A, making it possible to suppress the problems such as diffusion of impurities from the second semiconductor substrate 220 due to the reduction in the resistance of the well region.

Further, similarly to the pixel sharing unit 539 in FIG. 13A, the pixel sharing unit 539 in the drawing has a configuration in which the second connecting location 251 is disposed at a position different from the element isolating region 261. Therefore, the pixel sharing unit 539 in the drawing can easily form the second connecting location 251 while maintaining the impurity concentration in the well region of the second semiconductor substrate 220 at a low concentration.

The configuration of the imaging device 1 other than this is similar to the configuration of the imaging device 1 in the first embodiment of the present disclosure, and thus the description thereof will be omitted.

In this manner, in the imaging device 1 according to the fourth embodiment of the present disclosure, the second connecting location 251 is disposed at a position different from the element isolating region 261. This makes it possible to facilitate formation of the second connecting location 251.

### 5. Application Examples

FIG. 14 depicts an example of a schematic configuration of an imaging system 7 including the imaging device 1 according to the embodiments and their modifications.

The imaging system 7 is, for example, an electronic device exemplified by an imaging device such as a digital still camera or a video camera, or a portable terminal device such as a smartphone or a tablet terminal. The imaging system 7 includes, for example, the imaging device 1 according to the above-described embodiments and their modifications, a DSP circuit 743, frame buffer memory 744, a display section 745, a storage section 746, an operation section 747, and a power supply section 748. In the imaging system 7, the imaging device 1 according to the above-described embodiments and their modifications, the DSP circuit 743, the frame buffer memory 744, the display section 745, the storage section 746, the operation section 747, and the power supply section 748 are connected to each other via a bus line 749.

The imaging device 1 according to the above-described embodiments and their modifications outputs image data according to incident light. The DSP circuit 743 is a signal processing circuit that processes a signal (image data) output from the imaging device 1 according to the above-described embodiments and their modifications. The frame buffer memory 744 temporarily holds the image data processed by the DSP circuit 743 in units of frames. The display section 745 includes, for example, a panel-type display device such as a liquid crystal panel or an organic electro luminescence (EL) panel, and displays a moving image or a still image captured by the imaging device 1 according to the above-described embodiments and their modifications. The storage section 746 records image data of a moving image or a still image captured by the imaging device 1 according to the above-described embodiments and their modifications in a recording medium such as semiconductor memory or a hard disk. The operation section 747 issues operation commands for various functions of the imaging system 7 in accordance with an operation by the user. The power supply section 748 appropriately supplies various types of power as operation power of the imaging device 1 according to the above-described embodiments and their modifications, the DSP circuit 743, the frame buffer memory 744, the display section 745, the storage section 746, and the operation section 747 to these supply targets.

Next, an imaging procedure in the imaging system 7 will be described.

FIG. 15 depicts an example of a flowchart of an imaging operation in the imaging system 7. A user instructs start of imaging by operating the operation section 747 (step S101). Subsequently, the operation section 747 transmits an imaging command to the imaging device 1 (step S102). Having received the imaging command, the imaging device 1 (specifically, a system control circuit 36) executes imaging by a predetermined imaging method (step S103).

The imaging device 1 outputs image data obtained by imaging to the DSP circuit 743. Here, the image data represents data for all the pixels of the pixel signal generated on the basis of the charge temporarily held in the floating diffusion FD. The DSP circuit 743 performs predetermined signal processing (for example, noise reduction processing) on the basis of the image data input from the imaging device 1 (step S104). The DSP circuit 743 causes the frame buffer memory 744 to hold the image data subjected to predetermined signal processing, and then, the frame buffer memory 744 causes the storage section 746 to store the image data (step S105). In this manner, imaging in the imaging system 7 is performed.

In the present application example, the imaging device 1 according to the above-described embodiments and their modifications is applied to the imaging system 7. With this application, the imaging device 1 can be downsized or have high definition, making it possible to provide the small or high definition imaging system 7.

### 6. Example of Application to Mobile Body

The technology according to the present disclosure (the present technology) is applicable to various products. For example, the technology according to the present disclosure may be applied to devices mounted on any of mobile body such as automobiles, electric vehicles, hybrid electric vehicles, motorcycles, bicycles, personal mobility, airplanes, drones, ships, and robots.

FIG. 16 is a block diagram depicting an example of schematic configuration of a vehicle control system as an example of a mobile body control system to which the technology according to an embodiment of the present disclosure can be applied.

A vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

FIG. 17 is a diagram depicting an example of the installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Hereinabove, an example of the vehicle control system to which the technology according to the present disclosure is applicable has been described. The technology according to the present disclosure can be suitably applied to the imaging section 12031 among the configurations described above. Specifically, the imaging device 1 in FIG. 1 can be applied to the imaging section 12031. By applying the technology according to the present disclosure to the imaging section 12031, it is possible to downsize the imaging section 12031.

### 7. Example of Application to Endoscopic Surgery System

The technology according to the present disclosure (the present technology) is applicable to various products. For example, the techniques according to the present disclosure may be applied to endoscopic surgery systems.

FIG. 18 is a view depicting an example of a schematic configuration of an endoscopic surgery system to which the technology according to an embodiment of the present disclosure (present technology) can be applied.

In FIG. 18, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 19 is a block diagram depicting an example of a functional configuration of the camera head 11102 and the CCU 11201 depicted in FIG. 18.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101. The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technique according to the present disclosure can be applied to, for example, the endoscope 11100 and the image pickup unit 11402 of the camera head 11102 among the configurations described above. Specifically, the imaging device 1 in FIG. 1 can be applied to the image pickup unit 11402. By applying the technology according to the present disclosure to the image pickup unit 11402, it is possible to downsize the image pickup unit 11402.

Although the endoscopic surgery system has been described here as an example, the technique according to the present disclosure may be applied to, for example, a microscopic surgery system or the like.

Note that the amplification transistor 213, the selection transistor 214, and the charge transfer section 102 of the pixel sharing unit 539 can also be constituted with a planar type MOS transistor such as the capacitance switching transistor 212 in FIG. 7. Further, the reset transistor 211 and the capacitance switching transistor 212 can be formed in the shape of a fin FET. In this manner, the amplification transistor 213 and the like can be constituted with transistors of various shapes.

Note that the configuration of the second embodiment of the present disclosure can be applied to other embodiments. Specifically, the second connecting location 254 in FIG. 9 can be applied to the third and fourth embodiments of the present disclosure.

### Effects

The imaging element (pixel array section 540) includes the first semiconductor substrate 120 and the second semiconductor substrate 220. The first semiconductor substrate 120 includes the photoelectric conversion section 101 that performs photoelectric conversion of incident light. The second semiconductor substrate 220 includes: the pixel circuit 210 that generates an image signal according to a charge generated by the photoelectric conversion; the element isolating region 261 that isolates elements of the pixel circuit 210; and the high impurity concentration region 225 which is disposed below the element isolating region 261 and having a high impurity concentration and is connected to the first semiconductor substrate 120 in order to use the reference potential in common. In addition, the first semiconductor substrate 120 is stacked on the back surface side of the second semiconductor substrate 220. This has an effect that the high impurity concentration region 225 connected to the first semiconductor substrate 120 is disposed in the element isolating region 261 in order to allow the reference potential to be used in common. This makes it possible to reduce the area of the second semiconductor substrate 220.

In addition, the semiconductor device may further include the connecting location 151 that connects the high impurity concentration region 225 and the first semiconductor substrate 120 to each other. With this configuration, the reference potentials of the first semiconductor substrate 120 and the second semiconductor substrate 220 can be used in common.

In addition, the high impurity concentration region 225 may be disposed in the well region of the second semiconductor substrate 220, and the connecting location 151 may connect the high impurity concentration region 225 and the well region of the first semiconductor substrate 120 to each other. This makes it possible to allow the well potential of the first semiconductor substrate 120 and the second semiconductor substrate 220 to be used in common.

In addition, the connecting location 151 may be formed of silicon. This makes it possible to adopt a high-temperature process in the subsequent manufacturing steps.

It is allowable to further provide the second connecting location 251 that is disposed on the front surface side of the second semiconductor substrate 220 and supplies the reference potential. This makes it possible to supply the reference potential to the first semiconductor substrate 120 and the second semiconductor substrate 220.

The second connecting location 251 may be disposed in the element isolating region 261 and connected to the high impurity concentration region 225. This has an effect of having a configuration in which the second connecting location 251 and the connecting location 151 are stacked via the high impurity concentration region 225. This makes it possible to reduce the resistance between the second connecting location 251 and the connecting location 151.

The second connecting location 251 may be disposed adjacent to the element isolating region 261. This makes it possible to reduce the resistance between the second connecting location 251 and the connecting location 151.

It is also allowable to further include the third semiconductor substrate 320 stacked on the front surface side of the second semiconductor substrate 220 and connected to the second connecting location 251. This makes it possible to supply the reference potential from the third semiconductor substrate 320.

The second connecting location 251 may be formed of metal.

The second connecting location 251 may be formed of silicon.

The high impurity concentration region 225 may have an impurity concentration of 5×10¹⁷ cm⁻³ or more. This makes it possible to reduce the resistance between the second connecting location 251 and the connecting location 151.

Further, the first semiconductor substrate 120 may include: the charge holding section 103 that holds the charge generated by the photoelectric conversion; and the charge transfer section 102 that transfers the charge from the photoelectric conversion section 101 to the charge holding section 103. The pixel circuit 210 may generate an image signal according to the held charge.

In addition, it is also allowable to further include a semiconductor region disposed in the same layer as the second semiconductor substrate 220.

In addition, a reference potential different from the reference potential may be supplied to the semiconductor region.

In addition, the high impurity concentration region 225 may be disposed in a well region of the second semiconductor substrate 220, and the semiconductor region may be configured in a well region of a conductivity type different from the well region of the second semiconductor substrate 220. This makes it possible to use complementary elements.

Further, it is also allowable to dispose, in the semiconductor region, the amplification transistor 213 that amplifies a signal based on a charge generated by the photoelectric conversion in the pixel circuit 210. With this configuration, the amplification transistor 213 can be isolated from the well region of the second semiconductor substrate 220.

Further, it is also allowable to dispose, in the semiconductor region, a selection transistor 214 that controls the output of the image signal in the pixel circuit 210. With this configuration, the selection transistor 214 can be isolated from the well region of the second semiconductor substrate 220.

The imaging device 1 includes: the first semiconductor substrate 120; the second semiconductor substrate 220; and the column signal processing section 550. The first semiconductor substrate 120 includes the photoelectric conversion section 101 that performs photoelectric conversion of incident light. The second semiconductor substrate 220 includes: the pixel circuit 210 that generates an image signal according to a charge generated by the photoelectric conversion; the element isolating region 261 that isolates elements of the pixel circuit 210; and the high impurity concentration region 225 which is disposed below the element isolating region 261 and having a high impurity concentration and is connected to the first semiconductor substrate 120 in order to use the reference potential in common. In addition, the first semiconductor substrate 120 is stacked on the back surface side of the second semiconductor substrate 220. The column signal processing section 550 processes the generated image signal. This has an effect that the high impurity concentration region 225 connected to the first semiconductor substrate 120 is disposed in the element isolating region 261 in order to allow the reference potential to be used in common. This makes it possible to reduce the area of the second semiconductor substrate 220.

The effects described in the present specification are merely examples, and thus, there may be other effects, not limited to the exemplified effects.

Note that the present technique can also have the following configurations.

(1) An imaging element comprising:
a first semiconductor substrate including a photoelectric conversion section that performs photoelectric conversion of incident light; and
a second semiconductor substrate that includes a pixel circuit that generates an image signal according to a charge generated by the photoelectric conversion, an element isolating region that isolates elements of the pixel circuit, and a high impurity concentration region which is disposed below the element isolating region and having a high impurity concentration and is connected to the first semiconductor substrate in order to use a reference potential in common, with the first semiconductor substrate being stacked on a back surface side of the second semiconductor substrate.
   (2) The imaging element according to the above (1), further comprising a connecting location that connects the high impurity concentration region and the first semiconductor substrate to each other.
   (3) The imaging element according to the above (2), wherein the high impurity concentration region is disposed in a well region of the second semiconductor substrate, and the connecting location connects the high impurity concentration region and the well region of the first semiconductor substrate to each other.
   (4) The imaging element according to the above (2) or (2), wherein the connecting location is formed of silicon.
   (5) The imaging element according to any one of the above (2) to (4), further comprising a second connecting location that is disposed on a front surface side of the second semiconductor substrate and supplies the reference potential.
   (6) The imaging element according to the above (5), wherein the second connecting location is disposed in the element isolating region and connected to the high impurity concentration region.
   (7) The imaging element according to the above (5), wherein the second connecting location is disposed adjacent to the element isolating region.
   (8) The imaging element according to any one of the above (5) to (7), further comprising a third semiconductor substrate stacked on a front surface side of the second semiconductor substrate and connected to the second connecting location.
   (9) The imaging element according to any one of the above (5) to (8), wherein the second connecting location is formed of metal.
   (10) The imaging element according to any one of the above (5) to (8), wherein the second connecting location is formed of silicon.
   (11) The imaging element according to any one of the above (1) to (10), wherein the high impurity concentration region has an impurity concentration of 5×10¹⁷ cm⁻³ or more.
   (12) The imaging element according to any one of the above (1) to (11),
wherein the first semiconductor substrate includes: a charge holding section that holds a charge generated by the photoelectric conversion; and a charge transfer section that transfers the charge from the photoelectric conversion section to the charge holding section, and
the pixel circuit generates an image signal according to the held charge.
   (13) The imaging element according to any one of the above (1) to (12), further comprising a semiconductor region disposed in a layer same as a layer of the second semiconductor substrate.
   (14) The imaging element according to the above (13), wherein a reference potential different from the reference potential is supplied to the semiconductor region.
   (15) The imaging element according to the above (14),
wherein the high impurity concentration region is disposed in a well region of the second semiconductor substrate, and
the semiconductor region is configured in a well region having a conductivity type different from a conductivity type of a well region of the second semiconductor substrate.
   (16) The imaging element according to any one of the above (13) to (15), wherein a transistor that amplifies a signal based on a charge generated by the photoelectric conversion in the pixel circuit is disposed in the semiconductor region.
   (17) The imaging element according to any one of the above (13) to (16), wherein a transistor that controls output of the image signal in the pixel circuit is disposed in the semiconductor region.
   (18) An imaging device comprising:
a first semiconductor substrate including a photoelectric conversion section that performs photoelectric conversion of incident light;
a second semiconductor substrate that includes a pixel circuit that generates an image signal according to a charge generated by the photoelectric conversion, an element isolating region that isolates elements of the pixel circuit, and a high impurity concentration region which is disposed below the element isolating region and having a high impurity concentration and is connected to the first semiconductor substrate in order to use a reference potential in common, with the first semiconductor substrate being stacked on a back surface side of the second semiconductor substrate; and
a processing circuit that processes the generated image signal.

### REFERENCE SIGNS LIST

1 IMAGING DEVICE
100 FIRST SUBSTRATE
100S, 200S, 300S SEMICONDUCTOR LAYER
100T, 200T, 300T WIRING LAYER
101, 101A, 101B, 101C, 101D PHOTOELECTRIC CONVERSION SECTION
102, 102A, 102B, 102C, 102D CHARGE TRANSFER SECTION
103, 103A, 103B, 103C, 103D CHARGE HOLDING SECTION
120 FIRST SEMICONDUCTOR SUBSTRATE
123, 123A, 123B SEMICONDUCTOR REGION
151, 151A, 151B CONNECTING LOCATION
210 PIXEL CIRCUIT
211 RESET TRANSISTOR
212 CAPACITANCE SWITCHING TRANSISTOR
213 AMPLIFICATION TRANSISTOR
214 SELECTION TRANSISTOR
200 SECOND SUBSTRATE
220 SECOND SEMICONDUCTOR SUBSTRATE
225, 225A, 225B HIGH IMPURITY CONCENTRATION REGION
226 SEMICONDUCTOR REGION
251, 251A, 251B, 254 SECOND CONNECTING LOCATION
261, 261A, 261B ELEMENT ISOLATING REGION
262 SUBSTRATE ISOLATING REGION
300 THIRD SUBSTRATE
320 THIRD SEMICONDUCTOR SUBSTRATE
539 PIXEL SHARING UNIT
540 PIXEL ARRAY SECTION
541, 541A, 541B, 541C, 541D PIXEL
550 COLUMN SIGNAL PROCESSING SECTION
11402, 12031, 12101 to 12105 IMAGING SECTION

1. An imaging element comprising:
a first semiconductor substrate including a photoelectric conversion section that performs photoelectric conversion of incident light; and
a second semiconductor substrate that includes a pixel circuit that generates an image signal according to a charge generated by the photoelectric conversion, an element isolating region that isolates elements of the pixel circuit, and a high impurity concentration region which is disposed below the element isolating region and having a high impurity concentration and is connected to the first semiconductor substrate in order to use a reference potential in common, with the first semiconductor substrate being stacked on a back surface side of the second semiconductor substrate.

2. The imaging element according to claim 1, further comprising a connecting location that connects the high impurity concentration region and the first semiconductor substrate to each other.

3. The imaging element according to claim 2,
wherein the high impurity concentration region is disposed in a well region of the second semiconductor substrate, and
the connecting location connects the high impurity concentration region and the well region of the first semiconductor substrate to each other.

4. The imaging element according to claim 2, wherein the connecting location is formed of silicon.

5. The imaging element according to claim 2, further comprising a second connecting location that is disposed on a front surface side of the second semiconductor substrate and supplies the reference potential.

6. The imaging element according to claim 5, wherein the second connecting location is disposed in the element isolating region and connected to the high impurity concentration region.

7. The imaging element according to claim 5, wherein the second connecting location is disposed adjacent to the element isolating region.

8. The imaging element according to claim 5, further comprising a third semiconductor substrate stacked on a front surface side of the second semiconductor substrate and connected to the second connecting location.

9. The imaging element according to claim 5, wherein the second connecting location is formed of metal.

10. The imaging element according to claim 5, wherein the second connecting location is formed of silicon.

11. The imaging element according to claim 1, wherein the high impurity concentration region has an impurity concentration of 5×10¹⁷ cm⁻³ or more.

12. The imaging element according to claim 1,
wherein the first semiconductor substrate includes: a charge holding section that holds a charge generated by the photoelectric conversion; and a charge transfer section that transfers the charge from the photoelectric conversion section to the charge holding section, and
the pixel circuit generates an image signal according to the held charge.

13. The imaging element according to claim 1, further comprising a semiconductor region disposed in a layer same as a layer of the second semiconductor substrate.

14. The imaging element according to claim 13, wherein a reference potential different from the reference potential is supplied to the semiconductor region.

15. The imaging element according to claim 14,
wherein the high impurity concentration region is disposed in a well region of the second semiconductor substrate, and
the semiconductor region is configured in a well region having a conductivity type different from a conductivity type of a well region of the second semiconductor substrate.

16. The imaging element according to claim 13, wherein a transistor that amplifies a signal based on a charge generated by the photoelectric conversion in the pixel circuit is disposed in the semiconductor region.

17. The imaging element according to claim 13, wherein a transistor that controls output of the image signal in the pixel circuit is disposed in the semiconductor region.

18. An imaging device comprising:
a first semiconductor substrate including a photoelectric conversion section that performs photoelectric conversion of incident light;
a second semiconductor substrate that includes a pixel circuit that generates an image signal according to a charge generated by the photoelectric conversion, an element isolating region that isolates elements of the pixel circuit, and a high impurity concentration region which is disposed below the element isolating region and having a high impurity concentration and is connected to the first semiconductor substrate in order to use a reference potential in common, with the first semiconductor substrate being stacked on a back surface side of the second semiconductor substrate; and
a processing circuit that processes the generated image signal.
